(19) United States
(12) Patent Application Publication
(10) Pub. No.: US 2023/0238770 A1
(43) Pub. Date: Jul. 27, 2023

(54) SEMICONDUCTOR PACKAGE FOR AN EDGE EMITTING LASER DIODE

(71) Applicant: MATERION CORPORATION, Mayfield Heights, OH (US)

(72) Inventors: Reto KELLER, Wetzikon ZH (CH); Richard KOBA, Saugus, MA (US); Daniel MARXER, Eschen (LI); Simon STAHEL, Chur (CH)

(21) Appl. No.: 18/099,687

(22) Filed: Jan. 20, 2023

Related U.S. Application Data
(60) Provisional application No. 63/302,325, filed on Jan. 24, 2022.

(51) Int. Cl. H01S 5/02257; H01S 5/02208; H01S 5/00

(52) U.S. Cl. CPC H01S 5/02257; H01S 5/02208; H01S 5/0064; H01S 5/023

(57) ABSTRACT

Provided herein is a semiconductor package and method of forming the same. The semiconductor package has a cap including a first window wafer with a first face and opposing second face, a second window wafer, and a perforated spacer wafer with through-holes extending therethrough. The first and second faces of the first window wafer are mutually parallel and at least one face includes an antireflective surface. The spacer wafer is disposed between the first and second window wafers with the first and second window wafers bonded to opposing faces of the spacer wafer. The window wafers and spacer wafer together define a cavity in the cap. An edge-emitting laser diode is disposed on a submount and configured to direct a laser beam at normal incidence to the first face of the first window wafer. The cap is mounted on the submount with the edge-emitting laser diode enclosed in the cavity.

### RELATED APPLICATION DATA

This application claims the benefit of U.S. Provisional Application No. 63/302,325, filed on Jan. 24, 2022, which is incorporated by reference herein in its entirety.

### BACKGROUND

Conventional semiconductor packages for edge emitting laser diodes (EELD) include a cap consisting of a roof and four sidewalls that create a cup shape. The roof of the cap is a transparent window with two polished surfaces. The cap surrounds a semiconductor chip which either sends or receives photons through the window roof of the cap. Typical semiconductor chips enclosed by a standard cap include photodiodes, IR detectors, LEDs or VCSELs. A cross-section of a conventional EELD semiconductor package (e.g., a TO package) is shown in FIG. 1.

EELDs emit high intensity photons from the cleaved sidewall of a semiconductor chip. The conventional technique to implement an EELD that is disposed on a submount is to direct the laser beam 90° upward toward the window mounted inside a protective metal cap.

### SUMMARY

In accordance with an embodiment of the subject innovation, a semiconductor package is provided. The semiconductor package can comprise a cap. The cap can comprise a first window wafer comprising a first face and opposing second face. The first face and second face are mutually parallel and the first face and/or the second face includes an antireflective surface. The cap can further comprise a second window wafer comprising a first face and opposing second face; and a spacer wafer that is perforated with a plurality of through-holes extending from a first face of the spacer wafer to an opposing second face of the spacer wafer. The spacer wafer is disposed between the first window wafer and the second window wafer with the first window wafer bonded to the first face of the spacer wafer and the second window wafer bonded to the second face of the spacer wafer. The semiconductor package can further comprise an edge-emitting laser diode that is disposed on a submount and configured to direct a laser beam at normal incidence to the first face of the first window wafer. The cap is mounted on the submount with the edge-emitting laser diode enclosed in the cavity.

In accordance with another embodiment of the subject innovation, a semiconductor package is provided. The semiconductor package can comprise a cap. The cap can comprise a window wafer comprising a first face and opposing second face. The first face and second face are mutually parallel and the first face and/or second face includes an antireflective surface. The cap can further comprise a cavity wafer that includes an array of cavities extending from a first face of the cavity wafer towards an opposing second face of the cavity wafer and including a bottom. The window wafer is bonded to the first face of the cavity wafer. The semiconductor package can further comprise an edge-emitting laser diode that is disposed on a submount and configured to direct a laser beam at normal incidence to the first face of the window wafer. The cap is mounted on the submount with the edge-emitting laser diode enclosed in the cavity.

In accordance with another embodiment of the subject innovation, a method of manufacturing a cap for use in an EELD semiconductor package is provided. The method can comprise bonding first and second window wafers to opposing faces of a spacer wafer to form a bonded wafer sandwich in which the spacer wafer is disposed between the first window wafer and the second window wafer in the bonded wafer sandwich. The spacer wafer is perforated with a plurality of through-holes extending therethrough between the opposing faces of the spacer wafer and a face of the first window wafer and/or the second window wafer includes an antireflective surface. The method can further comprise stacking multiple bonded wafer sandwiches on top of one another to form a block, wherein adjacent bonded wafer sandwiches are secured together using an adhesive. The method can further comprise cutting through the block to form at least one plate and processing the plate by metallizing lip portions of the plate. The method can further comprise cutting through the plate to form bars and then removing the adhesive from the bars to produce caps.

In accordance with another embodiment of the subject innovation, a method of manufacturing a cap for use in an EELD semiconductor package is provided. The method can comprise bonding a window wafer to a cavity wafer to form a bonded wafer sandwich in which the cavity wafer includes an array of cavities that extend from a first face of the cavity wafer towards an opposing second face of the cavity wafer and include a bottom. A face of the window wafer includes an antireflective surface. The method can further comprise stacking multiple bonded wafer sandwiches on top of one another to form a block, wherein adjacent bonded wafer sandwiches are secured together using an adhesive. The method can further comprise cutting through the block to form at least one plate and processing the plate by metallizing lip portions of the plate. The method can comprise cutting through the plate to form bars and removing the adhesive from the bars to produce caps.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 is a cross-sectional view of a conventional semiconductor package for an edge emitting laser diode.

FIG. 2 is a cross-sectional view of an example embodiment of a semiconductor package for an EELD in accordance with the present disclosure.

FIGS. 3A through 3C are schematic illustrations of a set of components used to form the semiconductor package shown in FIG. 2. FIG. 3A is a schematic illustration of a window wafer shown in plan view (top) and side view (bottom). FIG. 3B is a schematic illustration of a perforated spacer wafer shown in plan view (top) and side view (bottom). FIG. 3C is a schematic illustration of a window wafer shown in plan view (top) and side view (bottom).

FIGS. 4A and 4B are schematic illustrations of a bonded wafer sandwich formed from the components shown in FIGS. 3A through 3C.

FIG. 5 is a plan view of the bonded wafer sandwich shown in FIGS. 4A-4B including cut lines for the process of singulation.

FIGS. 6A through 6C are schematic illustrations of a cap used to form the semiconductor package shown in FIG. 2. FIG. 6A is a top view, FIG. 6B is a front view, and FIG. 6C is a bottom view.

FIGS. 7A through 7C are schematic illustrations of a caps at various stages of processing. FIG. 7A is a schematic illustration of a subset of the wafer showing an array of caps including cut lines. FIG. 7B is a schematic illustration of a cap. FIG. 7C is a schematic illustration of a cap with a metallized lip.

FIGS. 8A and 8B are schematic illustrations of assembly of the EELD semiconductor package shown in FIG. 2. In FIG. 8A, the cap is not mounted on the submount. In FIG. 8B, the cap is mounted on the submount to an EELD chip in a cavity of the semiconductor package.

FIG. 9 is a cross-sectional view of another example embodiment of a semiconductor package for an EELD in accordance with the present disclosure.

FIGS. 10A and 10B are schematic illustrations of a set of components used to form the semiconductor package shown in FIG. 9. FIG. 10A is a schematic illustration of a window wafer shown in plan view (top) and side view (bottom). FIG. 10B is a schematic illustration of a cavity wafer shown in plan view (top) and side view (bottom).

FIGS. 11A and 11B are schematic illustrations of a bonded wafer formed from the components shown in FIGS. 10A and 10B.

FIG. 12 is a plan view of the bonded wafer shown in FIGS. 11A-11B including cut lines for the process of singulation.

FIGS. 13A through 13C are schematic illustrations of a cap used to form the semiconductor package shown in FIG. 9. FIG. 13A is a top view, FIG. 13B is a front view, and FIG. 13C is a bottom view.

FIGS. 14A through 14C are schematic illustration of wafer bonding to form a bonded three-wafer sandwich.

FIGS. 15A and 15B are schematic illustrations showing how bonded wafer sandwiches can be stacked and then cut vertically to create plates. In FIG. 15A, the bonded wafers of FIG. 14 are stacked. Vertical cutting paths are shown for a block of bonded wafer sandwiches. In FIG. 15B, cutting paths are shown for a plate.

FIG. 16 is a schematic illustration of bars produced by cutting the plates shown in FIG. 15B.

FIG. 17 is a cap liberated from the bars of FIG. 16.

FIG. 18 is a process flow diagram illustrating an example implementation of method for producing a cap from a stack of bonded wafers in accordance with this disclosure.

FIG. 19 is a process flow diagram illustrating an example implementation of a method for producing a cap from a bonded wafer sandwich in accordance with this disclosure.

FIG. 20 is a plan view of a bonded wafer sandwich including cut lines for forming strips.

FIG. 21 is a schematic illustration of strips mounted on a carrier shown in side view (top) and plan view (bottom) in accordance with this disclosure.

FIG. 22 is a plan view of mounted strips including cut lines for the process of singulation.

FIG. 23 is a process flow diagram illustrating another example implementation of a method for fabricating a cap by cutting a bonded wafer sandwich into strips which are processed.

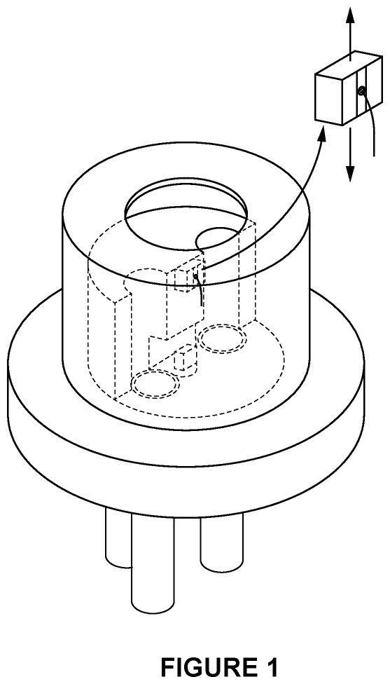

### DETAILED DESCRIPTION

A more complete understanding of the processes and apparatuses disclosed herein can be obtained by reference to the accompanying drawings. These figures are merely schematic representations based on convenience and the ease of demonstrating the existing art and/or the present development, and are, therefore, not intended to indicate relative size and dimensions of the assemblies or components thereof.

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

As used in the specification and in the claims, the terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of the enumerated ingredients/steps, which allows the presence of only the named ingredients/steps, along with any unavoidable impurities that might result therefrom, and excludes other ingredients/steps.

Numerical values in the specification and claims of this application should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable (for example, the range of “from 2 grams to 10 grams” is inclusive of the endpoints, 2 grams and 10 grams, and all the intermediate values).

The modifier “about” used in connection with a quantity is inclusive of the stated value and has the meaning dictated by the context (for example, it includes at least the degree of error associated with the measurement of the particular quantity). When used with a specific value, it should also be considered as disclosing that value. For example, the term “about 2” also discloses the value “2” and the range “from about 2 to about 4” also discloses the range “from 2 to 4.”

The edge-emitting laser diode (EELD) semiconductor package and cap fabrication method disclosed herein addresses an unmet need in the EELD industry for a lower cost, highly automatable surface mount package for EELD chips. In particular, the method provides a novel sequence of operations that results in a cap from a stack of bonded wafer stacks which results in a lower-cost surface mount package that can be assembled by robots.

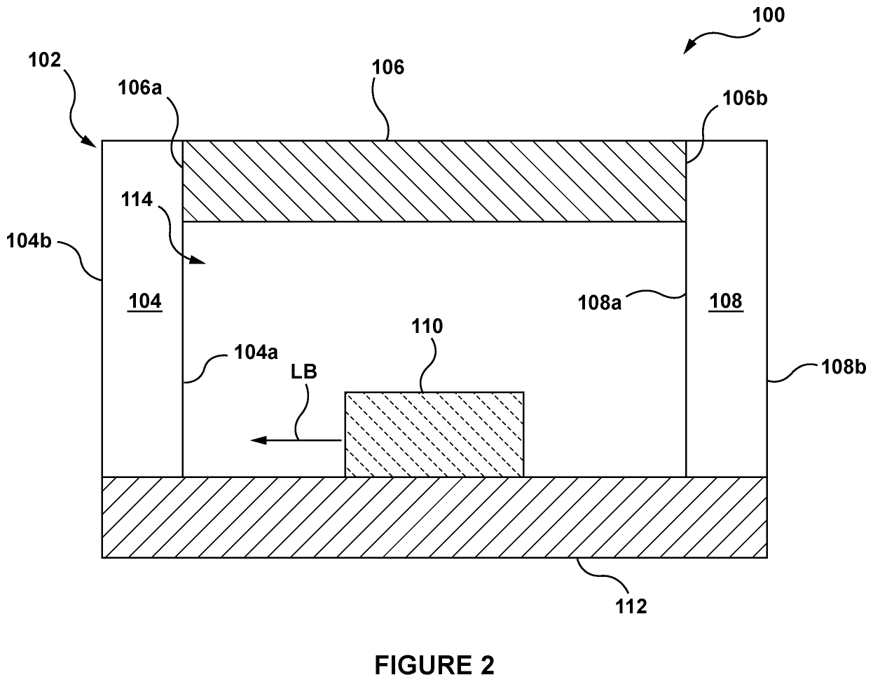

FIG. 2 is a cross-sectional view of an example embodiment of a semiconductor package 100 for an edge emitting laser diode (EELD) in accordance with the subject disclosure. The semiconductor package 100 can comprise a cap 102, a submount 112, and an edge emitting laser diode (EELD) 110 disposed on the submount 112. The cap 102 is configured to be mounted on the submount 112 to enclose the EELD 110 in a cavity 114 of the cap 102. The submount 112, when mounted to the cap 102, acts as a lid that covers or seals the cavity 114 with the EELD 110 disposed therein. The EELD 110 is configured to direct a laser beam LB through a sidewall of the cap 102 as described in more detail below.

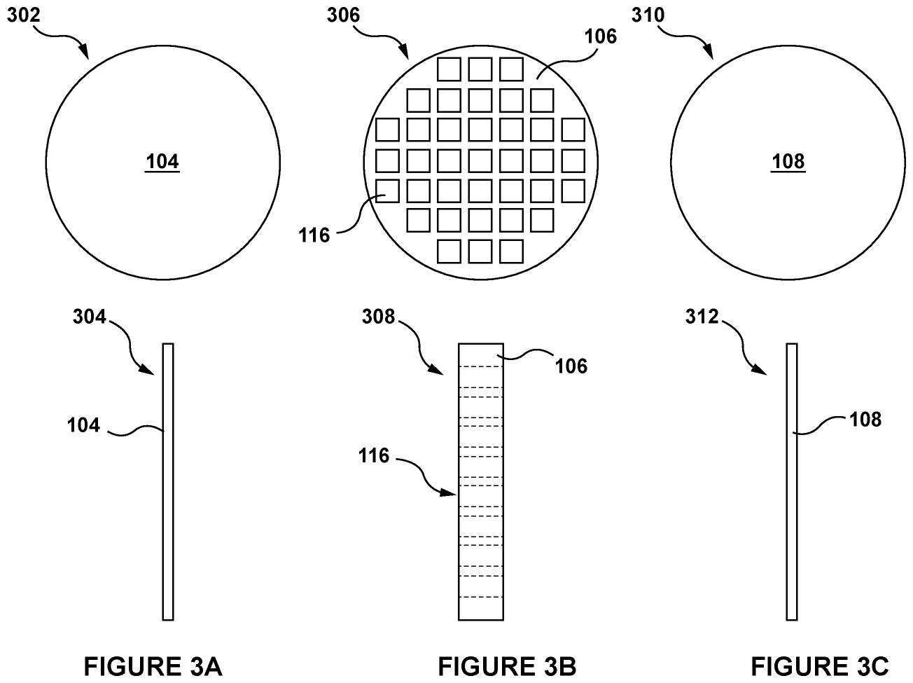

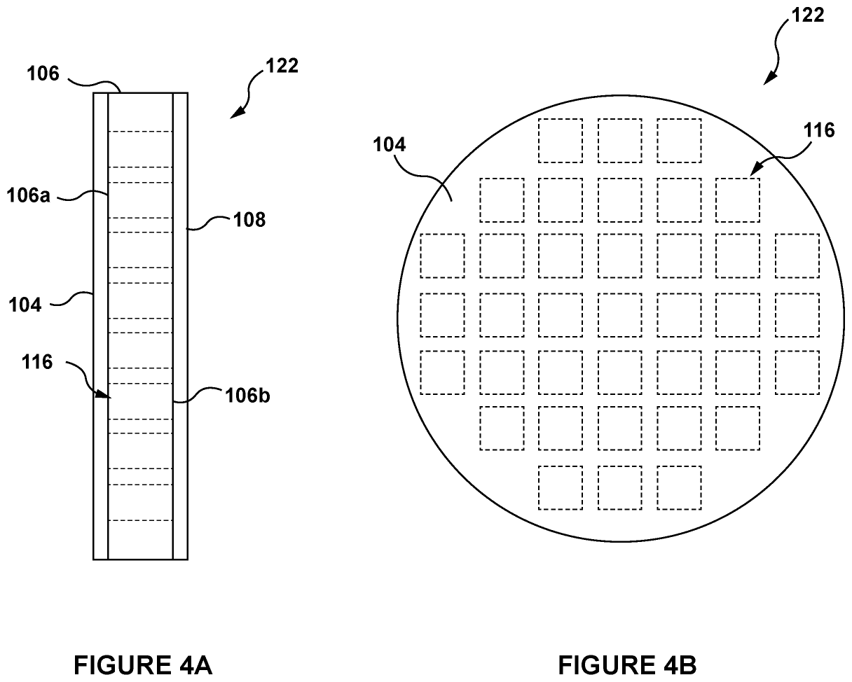

Referring now to FIGS. 2-8, the cap 102 can be a three-layer structure that comprises three wafers—a first window wafer 104, a second window wafer 108, and a spacer wafer 106. FIG. 3A illustrates the first window wafer 104 from a plan view 302 and a side view 304. FIG. 3B illustrates the spacer wafer 106 from a plan view 306 and a side view 308. FIG. 3C illustrates the second window wafer 108 from a plan view 310 and a side view 312. The spacer wafer 106 can be sandwiched between the first window wafer 104 and second window wafer 108, as shown in FIG. 4A. In some embodiments, the first window wafer 104 can comprise a first face 104a and opposing second face 104b. The second window wafer 108 can comprise a first face 108a and opposing second face 108b. The spacer wafer 106 can comprise a first face 106a and opposing second face 106b. The spacer wafer 106 is a perforated wafer with a plurality of through-holes 116 extending from the first face 106a of the spacer wafer 106 to the opposing second face 106b of the spacer wafer 106. The plurality of through-holes 116 are not limited to a specific shape and may include rectangular through-holes, triangular through-holes, and circular through-holes. In FIGS. 2-8, the spacer wafer 106 has a plurality of rectangular through-holes 116 extending from the first face 106a to the second face 106b. In an example, the plurality of through-holes 116 can be formed in the spacer wafer 106 through machining. By way of example and not limitation, through-holes 116 can be formed in brittle materials (e.g., silicon, glass, sapphire, among others) by laser cutting, waterjet cutting, photoetching, ultrasonic machining, and the like. It is to be appreciated that the through-holes 116 can be formed in the spacer wafer 106 by a technique that is selected with sound engineering judgment without departing from the scope of the subject innovation.

The spacer wafer 106 can be disposed between the first window wafer 104 and the second window wafer 108 with the first and second window wafers 104, 108 bonded to opposing faces 106a, 106b of the spacer wafer 106. For example, the first window wafer 104 can be bonded to the first face 106a and the second window wafer 108 can be bonded to the second face 106b. In still another example (not shown), the first window wafer 104 can be bonded to the second face 106b and the second window wafer 108 can be bonded to the first face 106a. By way of example and not limitation, the first and second window wafers 104, 108 can each have a thickness of approximately 0.2 mm to 0.8 mm. In another example, the first and second window wafers 104, 108 can have a thickness of 0.5 mm. By way of example and not limitation, the spacer wafer 106 can have a thickness of approximately 0.5 mm to 3.5 mm. In another example, the spacer wafer 106 can have a thickness of approximately 2 mm. It is to be appreciated that the first window wafer 104, the spacer wafer 106, and the second window wafer 108 may each have a circular shape with a diameter between approximately 150 mm and 200 mm. It is to be appreciated that the first window wafer 104, the spacer wafer 106, and the second window wafer 108 can each have a rectangular shape with a corresponding length and width. The thickness of the first window wafer 104, the second window wafer 108, and the spacer wafer 106 can be selected with sound engineering judgment without departing from the scope of the subject innovation.

The semiconductor package 100 is optimized for use with the EELD 110 based on the configuration of the first and/or second window wafer 104, 108 with respect to the laser beam LB emitted by the EELD 110.

In a particular example, the EELD 110 can be configured to direct a laser beam LB normal to the first face 104a and the second face 104b of the first window wafer 104. In these embodiments, the first window wafer 104 serves as the transmission window for photons emitted by the EELD 110 towards the first window wafer 104 at normal incidence. In such embodiments where the first window wafer 104 serves as the transmission window, the first face 104a and the second face 104b can be mutually parallel. In an embodiment, at least one face 104a, 104b of the first window wafer 104 that serves as the transmission window can include an antireflective (AR) surface. For example, the first window wafer 104 can be a dual side polished (DSP) wafer. Depending on the wavelength of the EELD 110, the first window wafer 104 can comprise DSP fused silica, glass, sapphire, or silicon. An advantage of the subject disclosure is that the laser beam LB from the EELD 110 can pass through the first window wafer 104 with minimal attenuation or distortion by employing a DSP window wafer having two parallel faces at normal incidence to the laser beam LB and further including an AR surface. The AR surface can be, but is not limited to, at least one of an AR coating, a filter coating, a textured surface, among others. In this example, the AR surface can be on at least one face 104a, 104b of the first window wafer 104.

In another example, the EELD 110 is configured to direct a laser beam LB normal to the first face 108a and the second face 108b of the second window wafer 108. In these embodiments, the second window wafer 108 serves as the transmission window for photons emitted by the EELD 110 towards the second window wafer 108 at normal incidence. In embodiments where the second window wafer 108 serves as the transmission window, the first face 108a and the second face 108b can be mutually parallel and at least one face 108a, 108b can include an AR surface. In some embodiments, the second window wafer 108 can be a dual side polished (DSP) wafer. Depending on the wavelength of the EELD 110, the second window wafer 108 can comprise DSP fused silica, glass, sapphire, or silicon. An advantage of the subject disclosure is that the laser beam LB from the EELD 110 can pass through the second window wafer 108 with minimal attenuation or distortion by employing a DSP window wafer having two parallel faces at normal incidence to the laser beam LB and further including an AR surface, wherein the AR surface can be, but is not limited to, at least one of an AR coating, a filter coating, a textured surface, among others. In this example, the AR surface can be on at least one face 108a, 108b of the second window wafer 108.

It is to be appreciated that at least one of the faces 104a, 104b, 108a, or 108b can include an AR surface. For example, a single face, such as the first face 104a, can include the AR surface. In another example, the first face 104a and second face 104b can include an AR surface. In another example, the second face 104b can include the AR surface. In another example, the first face 108a can include the AR surface. In still another example, the second face 108b can include the AR surface. In still another example, the first face 108a and second face 108b can include an AR surface. It is to be appreciated that the window wafer that will act as the transmission window for the EELD 110 can include at least one face with an AR surface. The laser beam LB from the EELD 110 can be transmitted through the window wafer sidewall with minimal attenuation or distortion by employing a DSP window wafer having two parallel faces at normal incidence to the laser beam LB and further including an AR surface (e.g., includes, but is not limited to, at least one of an AR coating, a filter coating, a textured surface, among others) on at least one face.

The semiconductor package 100 can be fabricated in less time while also reducing the amount of materials and/or cost compared to conventional techniques for EELD semiconductor packages. For example, the semiconductor package 100 does not include a mirror, which is used in conventional EELD semiconductor packages to reflect a laser beam 90° upward toward the roof of the cap that serves as the transmission window. Thus, conventional EELD semiconductor packages require very precise alignment of the EELD chip, the mirror and the window, and achieving such precise alignment makes mass production very challenging. The subject disclosure, on the other hand, facilitates transmission of the laser beam LB through the window wafer sidewall of the cap without requiring a mirror to reflect the laser beam.

It is contemplated that in some embodiments each of the first window wafer 104 and the second window wafer 108 are configured to act as the transmission window of the photons emitted by the EELD 110. In these embodiments, both the first and second window wafers 104, 108 can be DSP wafers and each of the first and second window wafers 104, 108 can include an AR surface on one or both faces 104a, 104b and 108a, 108b respectively.

For the sake of brevity, the following discussion in paragraphs [0049]-[0053] refer to embodiments in which the first window wafer 104 is the transmission window with first and second faces 104a, 104b arranged at normal incidence to the laser beam LB and with at least one of the first and second faces 104a, 104b including an AR surface. But, principles of the following discussion apply equally to embodiments in which the second window wafer 108 is the transmission window with first and second faces 108a, 108b arranged at normal incidence to the laser beam LB and with at least one of the first and second faces 108a, 108b including an AR surface.

By way of example and not limitation, the first face 104a of the first window wafer 104 can include the AR surface. In such example, it may be preferred that the first face 104a includes the AR surface because the first face 104a is disposed proximal to the EELD 110 while the second face 104b is disposed distal to the EELD 110. As such, the laser beam LB is at normal incidence to the first face 104a. In other examples, the first and second faces 104a, 104b of the first window wafer 104 can each include an AR surface. In still another example, the second face 104b of the first window wafer 104 can include the AR surface.

In another example, one or more AR surfaces can comprise an AR coating and/or a filter coating. In one non-limiting example, an AR coating can be applied to (e.g., deposited over) the first face 104a of the first window wafer 104. In some embodiments, the first window wafer 104 is a DSP wafer that includes an AR surface, for example an AR coating on at least one of the first face 104a, second face 104b, or a combination thereof. In another non-limiting example, a filter coating can be applied to (e.g., deposited over) at least one of the faces 104a, 104b, or a combination thereof in a 2-D array of rectangles to improve the quality of the laser beam LB emitted by the EELD 110. In yet another non-limiting example, the AR surface can comprise a high laser-induced damage threshold (LIDT) coating. A high LIDT, such as that of the high LIDT coating, may comprise a LIDT greater than 1 J/cm² for pulsed lasers at any given wavelength or over a wavelength range. As an example, a high LIDT may be at least 10 J/cm² for a near-infrared laser beam. For higher power laser beams emitted a short distance from the first window wafer 104, it is beneficial for the first window wafer 104 to include the high LIDT. The high LIDT coatings can be created by mitigating defects in the coatings.

In another example, one or more AR surfaces can comprise a textured surface configured to form an antireflective topography. In these embodiments, at least one of the first face 104a, second face 104b, or a combination thereof includes a textured surface for antireflection. The textured surface can provide a high LIDT, which may comprise a LIDT greater than 1 J/cm² for pulsed lasers at any given wavelength or over a wavelength range. In some embodiments, the textured surface can comprise textured areas that may be formed in a matrix of discrete rectangular areas. In one non-limiting example, the textured surface comprises a “motheye” topography. The texturing can be accomplished by wet or dry etching processes performed through a mask defined by lithography.

In still another example, one face 104a, 104b of the first window wafer 104 can have a textured surface for antireflection while the opposing face 104a, 104b can be textured to form a lens (e.g., a Fresnel lens or a modern metalens). In some embodiments, the monochromatic nature of the laser beam LB emitted by the EELD 110 can enhance compatibility with metalenses. Alternatively, in other embodiments, the second face 104b, which is disposed distal from the EELD 110 and forms part of the exterior (e.g., exterior face), can be bonded with an array of lenses or microlenses. In these embodiments, if the added lens has the same refractive index as the material comprising the first window wafer 104, then reflection losses can be minimized.

In an example, imprinted lenses can be applied to the first or second window wafers 104, 108 prior to wafer bonding as long as the imprinted lenses can endure the temperature and pressure of wafer bonding. Otherwise, the imprinted microlenses can be applied to the first or second window wafers 104, 108 after the wafer bonding and prior to the process of singulation.

In some embodiments, the spacer wafer 106 is configured to have a substantially similar (e.g., matching) coefficient of thermal expansion (CTE) as the first and second window wafers 104, 108. A technique to achieve substantially similar CTEs (hereinafter referred to as CTE matching) is by using the same material in the wafers 104, 106, and 108 (e.g., composition matching). As an example, the spacer wafer 106 can be comprised of the same material as the first and second window wafers 104, 108 to achieve CTE matching. In another embodiment, CTE matching can be achieved using alternative materials for the spacer wafer 106. In one non-limiting example, the cap 102 can comprise an Invar spacer wafer 106 and the first and second window wafers 104, 108 can comprise silicon or Borofloat 33 glass. In another non-limiting example, the cap 102 can comprise a silicon spacer wafer 106 and the first and second window wafers 104, 108 can comprise Borofloat 33 glass. In yet another non-limiting example, the cap 102 can comprise a Kovar spacer wafer 106 and the first and second window wafers 104, 108 can comprise sapphire. It is to be appreciated that the spacer wafer 106 can be Invar, silicon, Kovar, fused silica, glass, sapphire, among others. Further, it is to be appreciated that the first and second window wafers 104, 108 can be, but are not limited to, silicon, fused silica, glass, sapphire, Borofloat 33 glass, among others.

The spacer wafer 106 is disposed between the first window wafer 104 and the second window wafer 108 with the first and second window wafers 104, 108 bonded to opposing faces 106a, 106b of the spacer wafer 106, as shown in FIG. 4A. As a non-limiting example, the first face 104a of the first window wafer 104 can be bonded to the first face 106a of the spacer wafer 106 and the first face 108a of the second window wafer 108 can be bonded to the second face 106b of the spacer wafer 106. It is to be appreciated that various types of bonding can be utilized to bond the first and second window wafers 104, 108 to opposing faces 106a, 106b of the spacer wafer 106. The type of bonding to bond the spacer wafer 106 to the first window wafer 104 and the second window wafer 108 can be selected with sound engineering judgment without departing from the scope of the subject innovation.

For example, hermetic bonding can be used to bond the first window wafer 104 to the first face 106a of the spacer wafer 106 and to bond the second window wafer 108 to the second face 106b of the spacer wafer 106. The hermetic bonding can be accomplished in a vacuum wafer bonder using methods such as, but not limited to, solder bonding, direct bonding, anodic bonding, and the like. In a non-limiting example, solder bonding can be achieved by coating one face of the wafer (e.g., first and second window wafers 104, 108) with a solder (e.g., AuSn, CuSn, AuGe, AuSi, among others) and metallizing the matching areas on the opposite wafer (e.g., spacer wafer 106) with a solderable metal. In another non-limiting example, anodic bonding can be directly achieved by bonding an alkali-containing glass wafer (e.g., first and second window wafers 104, 108) to a Si or other glass wafer (e.g., spacer wafer 106). In another non-limiting example, a thin film of borosilicate glass can be deposited on a glass or metal wafer to enable anodic bonding. In yet another non-limiting example, direct bonding, also known as fusion bonding, can be performed at a temperature of approximately 400° C. to bond the first and second window wafers 104, 108 to opposing faces 106a, 106b of the spacer wafer 106. Direct bonding is sensitive to the surface roughness of the wafers because it relies on weak physical forces (e.g., the formation of covalent bonds between Si and silicon dioxide (SiO₂) substrates) that vanish at distances of just a few nanometers (nm). As such, the wafer surfaces have to be very smooth for fusion bonding; for example, the wafers may have surface roughness values (Ra) below 0.3 nm-0.5 nm.

In other embodiments, wafer bonding is incorporated to bond the first window wafer 104 to the first face 106a of the spacer wafer 106 and to bond the second window wafer 108 to the second face 106b of the spacer wafer 106. It is to be appreciated that the wafer bonding can be performed in a single step (e.g., bonding the spacer wafer 106 to the first window wafer 104 and the second window wafer 108), or in two successive steps (e.g., bonding the spacer wafer 106 to the first window wafer 104 and then the second window wafer 108 or vice versa).

In some embodiments, the wafer bonding can be performed at room temperature using a laser. It is to be appreciated that bonding a window wafer to a spacer wafer via laser bonding offers many advantages. First, the laser bonding can be performed at low temperature, such as at room temperature, which advantageously mitigates heat-related damage to any previously-formed optical coatings and other active layers. Thus, the first and second window wafers 104, 108 and/or spacer wafer 106 can be coated before laser treatment. Further, laser bonding provides a minimal heat load because the heat-affected zone (i.e., the laser treatment zone) is very small—for example, only a few micrometers. Beneficially, the low heat allows for the use of less bulk/material and, thus, permits the use of thinner materials. Second, laser bonding provides for direct bonding between the spacer wafer and window wafer without requiring additive materials, such as adhesives, and without leaving a gap between the window wafer (e.g., first window wafer 104 or second window wafer 108) and the spacer wafer (e.g., spacer wafer 106). It is to be appreciated that no adhesives means no outgassing and direct laser bonding does not require metal or metal-seed layers for bonding. In a non-limiting example, direct laser bonding for wafer-level chip scale packaging may permit glass-to-glass sealing.

It is to be appreciated that laser bonding is a wafer-level process that enables highly efficient and scalable device manufacturing. It is to be appreciated laser bonding helps to optimize the coefficient of thermal expansion (CTE) and CTE matching between wafer materials enables a strong, hermetic seal between the materials. In some non-limiting examples, laser bonding may be used to bond a glass spacer wafer to a glass window wafer, or a glass spacer wafer to a Si window wafer. It is conceivable that infrared (IR) lasers may be used as the laser source to bond a Si spacer wafer to a Si window wafer.

In some embodiments, the wafers 104, 106, 108 can be bonded together without forming a hermetic bond. In these embodiments, an organic adhesive can be used to bond the spacer wafer 106 to the first and second window wafers 104, 108. Preferably, the adhesive has minimal (e.g., where low outgassing adhesive is defined by NASA and ASTM E595) outgassing during B-staging and cure, but this is not required. It is to be appreciated that a cost reduction may be provided by not using hermetic bonding to bond the wafers 104, 106, 108 because anodic bonding and solder bonding require sophisticated wafer bonders, typically done under vacuum (e.g., costly process), whereas glue bonding can be done on a hot plate in air.

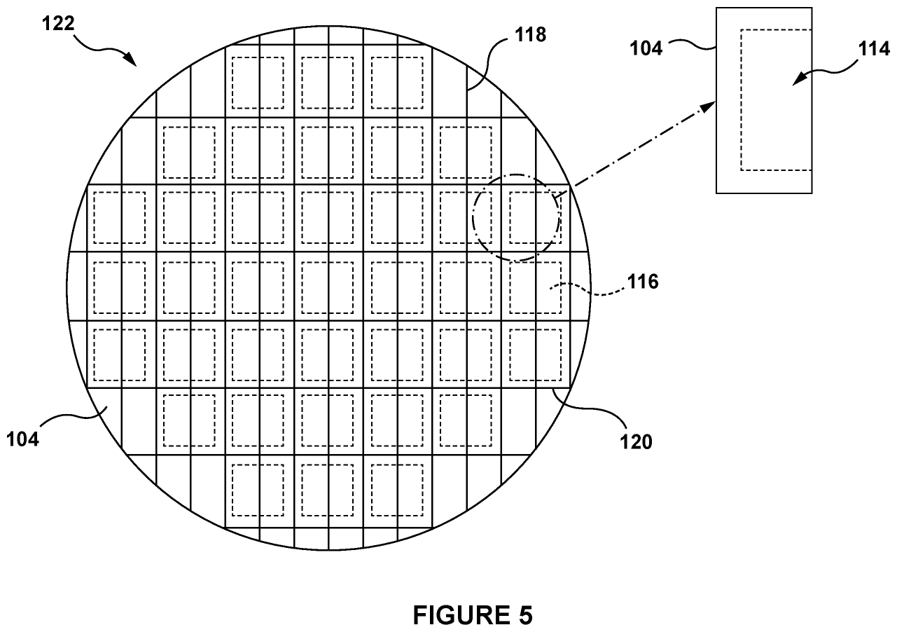

Referring now to FIGS. 4A-4B and 5, an example of a bonded wafer sandwich 122 (e.g., a stack of bonded wafers) is illustrated that includes three wafers—the first window wafer 104, the spacer wafer 106, and the second window wafer 108. In this embodiment, the spacer wafer 106 is disposed between (e.g., or sandwiched between) the first window wafer 104 and the second window wafer 108 with the first and second window wafers 104, 108 bonded to opposing faces 106a, 106b of the spacer wafer 106. The bonded wafer sandwich 122 can be oriented for dicing or sawing of the bonded wafer sandwich 122 into individual parts in order to produce caps 102 in a process referred to as singulation.

Prior to dicing/sawing, the bonded wafer sandwich 122 is positioned with a processed window wafer as the top surface. The processed window wafer is the DSP window wafer that is configured to serve as the transmission window. In the embodiment shown in FIG. 5, the first window wafer 104 is the top surface. The bonded wafer sandwich 122 can then be diced along cut lines 118 and 120 to produce the caps 102 by singulation. It is to be appreciated that the bonded wafer sandwich 122 can be diced along cut lines 118 and 120 at the same time or one at a time (e.g., sequentially).

FIG. 5 depicts cut lines 118 and 120 which extend through the bonded wafer sandwich 122. The cut lines 118 can be arranged to extend through the through-holes 116 (e.g., intersecting the through-holes 116) such that cutting downwards along the cut lines 118 cuts through the through-holes 116 within the bonded wafer sandwich 122 to form cavities 114. In some examples, the through-holes 116 are cut into sections of substantially equal dimensions which may provide substantially uniform cavities 114. The cut lines 120 can be arranged orthogonal to the cut lines 118. The cut lines 120 can be arranged to extend between the plurality of through-holes 116 without intersecting the through-holes 116 such that cutting downwards along the cut lines 120 cuts through three layers of wafer material. For example, dicing along cut lines 120 cuts through spacer wafer walls that define the through-holes 116 without the path of the cut lines 120 intersecting with the through-holes 116.

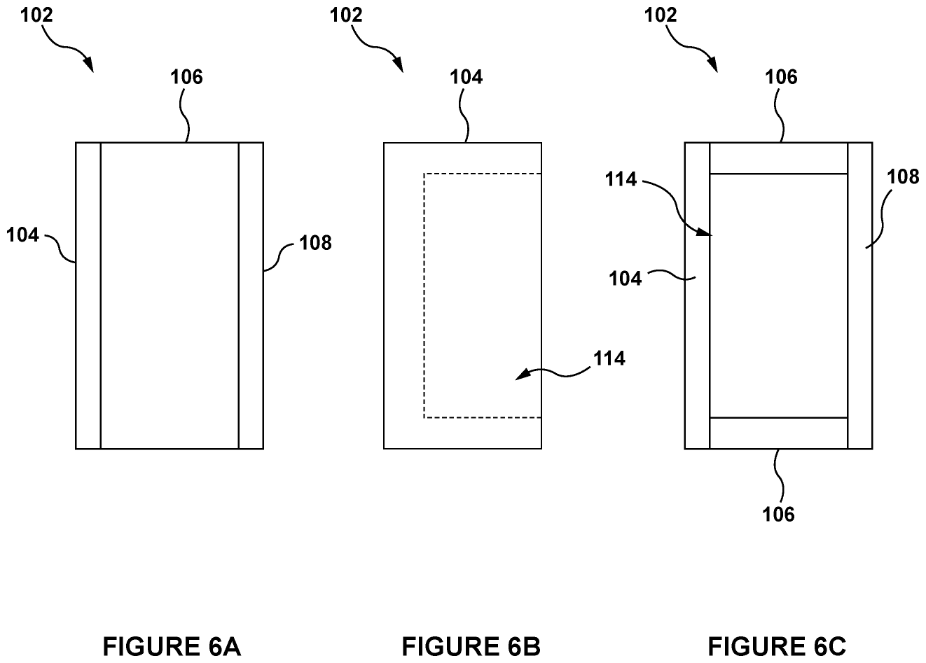

Dicing along cut lines 118 and 120, produces the caps 102 shown in FIGS. 6A through 6C. In some implementations, the cut lines 118 extend through rectangular through-holes 116 such that dicing along the cut lines 118 separates the larger rectangular through-hole 116 into two smaller rectangular openings that are substantially equal in size. In some implementations, the bonded wafer sandwich 122 can be diced along cut lines 118, 120 using a diamond saw, water jet, ultrasonic jet, or other suitable method. In some embodiments, the bonded wafer sandwich 122 can be either waxed down or on blue tape adhesive to hold the bonded wafer sandwich 122 during dicing.

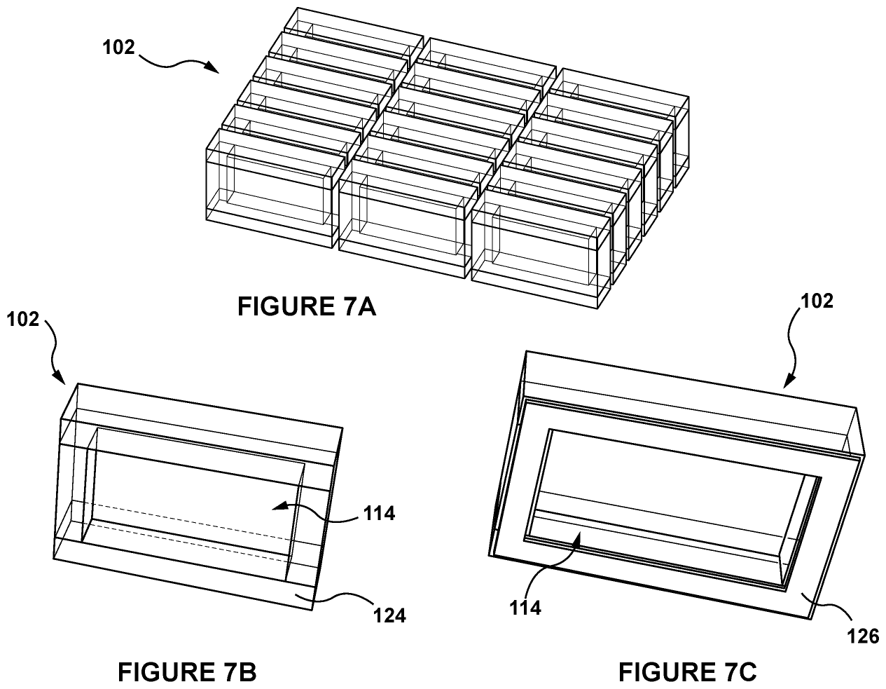

Referring now to FIGS. 6A-6C and 7, there is an example embodiment of a three-wafer cap 102 formed by singulation. In this embodiment, the cap 102 comprises four sidewalls and a lid or roof. In particular, the first window wafer 104 forms one sidewall of the cap 102, the second window wafer 108 forms a second sidewall of the cap 102, and the spacer wafer 106 forms two sidewalls and the roof of the cap 102. The first window wafer 104, the spacer wafer 106, and the second window wafer 108 together define an uncovered cavity 114 (e.g., open cavity) in the cap 102. In some embodiments, singulation results in a cap 102 in which two of the four sidewalls of each cap 102 comprise DSP window wafers.

Referring now to FIGS. 7A through 7C, there is an example of a cap 102 formed from dicing of the bonded wafer sandwich 122 shown in FIG. 5. The cap 102 can comprise a lip 124 that results from singulation. In some embodiments, the surface of the lip 124 can be grinded and/or polished to improve flatness and reduce surface roughness. In some embodiments, the interior width of the cavity 114 of the cap 102 after singulation has the same dimension as the thickness of the starting spacer wafer 106. In some examples, the thickness of the starting spacer wafer 106 is between 0.5 mm and 3.5 mm and the interior width of the cavity 114 of the cap 102 after singulation matches the thickness of the starting spacer wafer 106 and is between 0.5 mm and 3.5 mm. In one particular example, the thickness of the spacer wafer 106 is 2 mm and, after singulation, this thickness dimension of 2 mm becomes the interior width of the cavity 114 of the cap 102.

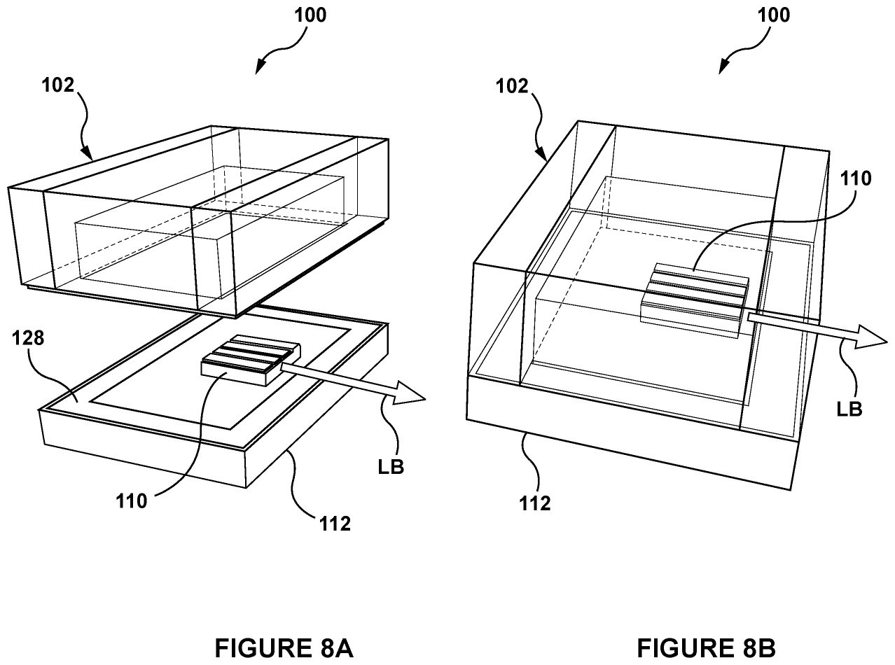

In some embodiments, the lip 124 can be metallized, such as by forming a metal surface 126 on the lip 124, to facilitate bonding of the lip 124 to a metal surface (e.g., 128 of FIGS. 8A-8B) on the submount (e.g., 112 of FIGS. 8A-8B). In some embodiments, the composition of the metal surface 126 can be selected to be compatible with (e.g., matching) the metal surface (e.g., 128 of FIGS. 8A-8B) on the submount (e.g., 112 of FIGS. 8A-8B). In an embodiment, metallizing the lip 124 can be performed by use of a paint or ink designed to form a hermetic, solderable metal surface on the lip 124. Since the lip 124 of each cap 102 is not defined until after singulation, metallization of the lip 124 can be done in a way that is compatible with mass production of caps 102. In some implementations, these paints or inks may require drying and firing steps in order to maximize the bond strength between the metal in the paint/ink and the material (e.g., glass, sapphire, silicon, among others) of the lip 124. Paints and inks are typically filled with metal particles or flakes such as Ni or Ag. The paint or ink can be applied to large quantities of these caps 102 using automated machines for pad printing or dip coating.

In some embodiments, the lip 124 of the cap 102 can be coated by a physical vapor deposition (PVD) process (e.g., sputtering or evaporation) with a thin film metallization stack if the ceiling of the cap 102 can be masked by a metal or photoresist. In these embodiments, the thin film metallization stack can comprise Gelot metallization of Materion Balzers Optics. It is to be appreciated that such a thin film metallization can enhance compatibility with solders.

Referring now to FIGS. 8A and 8B, there is a schematic illustration of the cap 102 enclosing the EELD 110 on a submount 112. In this embodiment, the cap 102 includes a metal surface 126 on the bottom lip 124 of the cap 102. When the cap 102 is mounted on the submount 112 the metal surface 126 engages a complimentary metal surface 128 on the submount 112. In some embodiments, the submount 112 is made of ceramic. In such embodiments, the EELD 110 is bonded to the ceramic submount 112 with vias to the backside (not shown). In an embodiment, a DSP metal spacer can be interposed between the EELD 110 and the submount 112 to provide vertical distance for the laser beam LB to fan out from the edge of the EELD chip before reaching the sidewall (e.g., first face 104a of the first window wafer 104 of FIG. 2). It is to be appreciated the semiconductor package 100 provided herein is smaller in footprint and volume, and is compatible with fully automated (robot) assembly. Additionally, the semiconductor package 100 provided herein permits the cap 102 to be mounted on a co-fired AIN submount 112 which provides better thermal performance than conventional semiconductor packages.

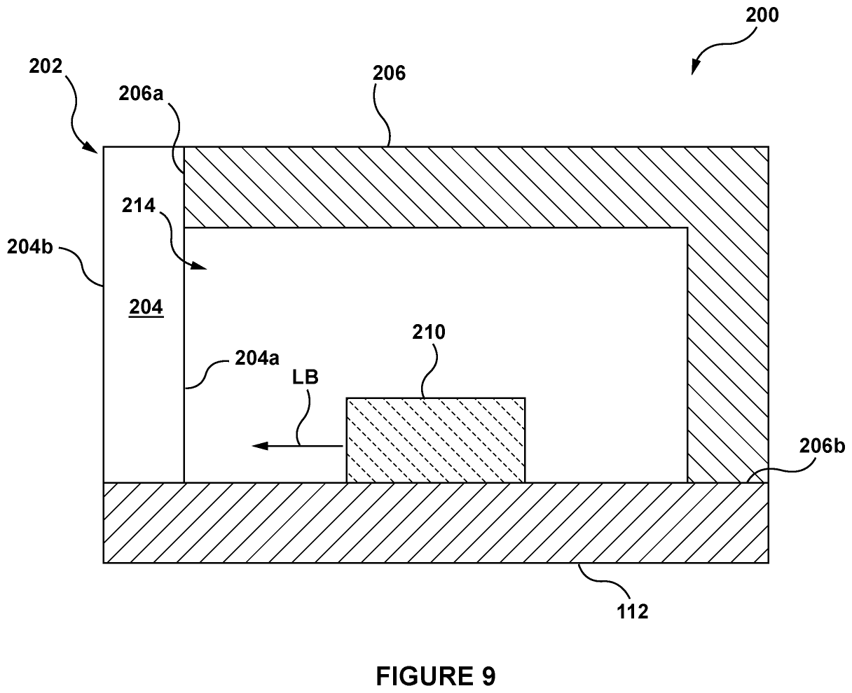

With reference to FIG. 9, there is a cross-sectional view of another example embodiment of a semiconductor package 200 for an edge emitting laser diode (EELD) in accordance with the subject disclosure. The semiconductor package 200 can comprise a cap 202, a submount 212, and an EELD 210 disposed on the submount 212. The cap 202 is configured to be mounted on the submount 212 to enclose the EELD 210 in a cavity 214 of the cap 202. The submount 212, when mounted to the cap 202, acts as a lid that covers or seals the cavity 214 with the EELD 210 disposed therein. The EELD 210 is configured to direct a laser beam LB through a sidewall of the cap 202 as described in more detail below.

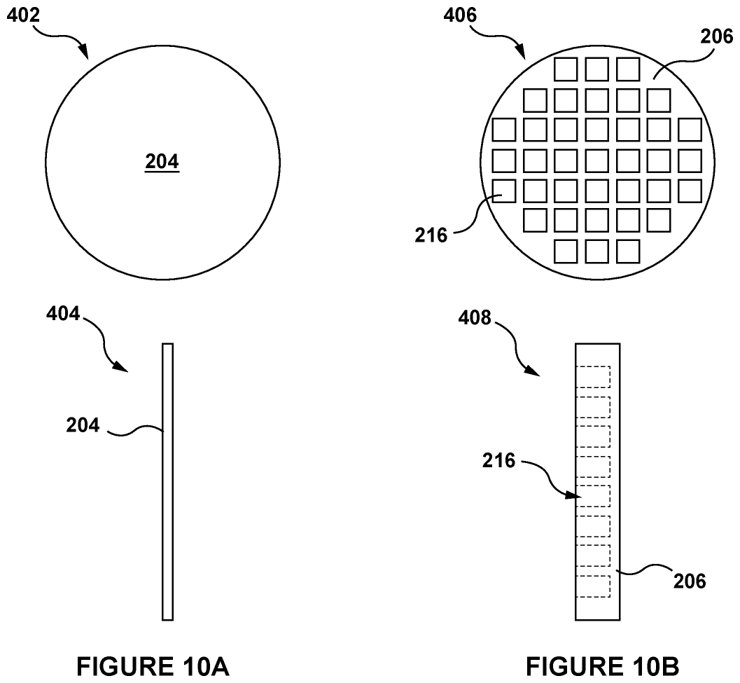

Referring now to FIGS. 9-13C, the cap 202 can be a two-layer structure that comprises two wafers—a window wafer 204 and a cavity wafer 206. FIG. 10A illustrates the window wafer 204 from a plan view 402 and a side view 404. FIG. 10B illustrates the cavity wafer 206 from a plan view 406 and a side view 408. In some embodiments, the window wafer 204 can comprise a first face 204a and opposing second face 204b. The cavity wafer 206 can include an array of cavities 216 extending from a first face 206a of the cavity wafer 206 towards an opposing second face 206b of the cavity wafer. The array of cavities 216 include a bottom such that the cavities do not extend entirely through the cavity wafer 206. The array of cavities 216 are not limited to a specific shape and may include rectangular cavities, triangular cavities, and circular cavities. In FIGS. 9-13C, the cavity wafer 206 has an array of rectangular cavities 216 extending from the first face 206a of the cavity wafer 206 towards the second face 206b of the cavity wafer 206 and including a bottom.

In an example, the array of cavities 216 can be formed in the cavity wafer 206 through machining. By way of example and not limitation, the array of cavities 216 can be formed by chemical etching, dry etching (e.g., deep reactive ion etching), ultrasonic machining, computer numerical control (CNC) machining, and the like. In some non-limiting examples, the cavities can be directly molded into a monolithic glass cavity wafer. In some non-limiting examples, the array of cavities 216 can be formed in a glass or Si cavity wafer by ultrasonic machining or wet etching. In other non-limiting examples, the array of cavities 216 can be formed in an Invar or Kovar cavity wafer by machining with an end mill or by wet etching. The flatness and surface roughness of the surface at the bottom of the cavities 216 are not critical, since the bottom of the cavity will become the ceiling in a cap 202. It is to be appreciated that the array of cavities 216 can be formed in the cavity wafer 206 by a technique that is selected with sound engineering judgment without departing from the scope of the subject innovation.

The cavity wafer 206 can be bonded to the first face 204a of the window wafer 204. In another example, the cavity wafer 206 can be bonded to the second face 204b of the window wafer 204. By way of example and not limitation, the window wafer 204 can have a thickness of approximately 0.2 mm to 0.8 mm. In another example, the window wafer 204 can have a thickness of 0.5 mm. By way of example and not limitation, the cavity wafer 206 can have a thickness of approximately 0.5 mm to 3.5 mm. In another example, the cavity wafer 206 can have a thickness of approximately 2 mm. It is to be appreciated that the window wafer 204 and the cavity wafer 206 may each have a circular shape with a diameter between approximately 150 mm and 200 mm. It is to be appreciated that the window wafer 204 and the cavity wafer 206 can each have a rectangular shape with a corresponding length and width. The thickness of the window wafer 204 and the cavity wafer 206 can be selected with sound engineering judgment without departing from the scope of the subject innovation.

The semiconductor package 200 is optimized for use with the EELD 210 based on the configuration of the window wafer 204 with respect to the laser beam LB emitted by the EELD 210.

In a particular example, the EELD 210 can be configured to direct a laser beam LB normal to the first face 204a and the second face 204b of the window wafer 204. In these embodiments, the window wafer 204 serves as the transmission window for photons emitted by the EELD 210 towards the window wafer 204 at normal incidence. In such embodiments where the window wafer 204 serves as the transmission window, the first face 204a and the second face 204b can be mutually parallel. In an embodiment, at least one face 204a, 204b of the window wafer 204 that serves as the transmission window can include an AR surface. In some embodiments, the window wafer 204 can be a dual side polished (DSP) wafer. Depending on the wavelength of the EELD 210, the window wafer 204 can comprise DSP fused silica, glass, sapphire, or silicon. An advantage of the subject disclosure is that the laser beam LB from the EELD 210 can pass through the window wafer 204 with minimal attenuation or distortion by employing a DSP window wafer having two parallel faces at normal incidence to the laser beam LB and further including an AR surface. The AR surface can be, but is not limited to, at least one of an AR coating, a filter coating, a textured surface, among others. In this example, the AR surface can be on at least one face 204a, 204b of the window wafer 204.

It is to be appreciated that at least one of the faces 204a, 204b can include an AR surface. For example, a single face, such as the first face 204a, can include the AR surface. In another example, the first face 204a and second face 204b can include an AR surface. In yet another example, the second face 204b can include the AR surface.

It is to be appreciated that the window wafer 204 that acts as the transmission window for the EELD 210 can include at least one face with an AR surface. The laser beam LB from the EELD 210 can be transmitted through the window wafer sidewall with minimal attenuation or distortion by employing a DSP window wafer having two parallel faces at normal incidence to the laser beam LB and further including an AR surface (e.g., includes, but is not limited to, at least one of an AR coating, a filter coating, a textured surface, among others) on at least one face.

The semiconductor package 200 can be fabricated in less time while also reducing the amount of materials and/or cost compared to conventional techniques for EELD semiconductor packages. For example, the semiconductor package 200 does not include a mirror, which is used in conventional EELD semiconductor packages to reflect a laser beam 90° upward toward the roof of the cap that serves as the transmission window. Thus, conventional EELD semiconductor packages require very precise alignment of the EELD chip, the mirror and the window, and achieving such precise alignment makes mass production very challenging. The subject disclosure, on the other hand, facilitates transmission of the laser beam LB through the window wafer sidewall of the cap without requiring a mirror to reflect the laser beam.

In the following embodiments, the window wafer 204 is the transmission window with first and second faces 204a, 204b arranged at normal incidence to the laser beam LB and with at least one of the first and second faces 204a, 204b including an AR surface.

By way of example and not limitation, the first face 204a, 204b of the window wafer 204 can include an AR surface. In such example, it may be preferred that the first face 204a includes the AR surface because the first face 204a is disposed proximal to the EELD 210 while the second face 204b is disposed distal to the EELD 110. As such, the laser beam LB is at normal incidence to the first face 204a. In other examples, both faces 204a, 204b of the window wafer 204 can include the AR surface.

In another example, one or more AR surfaces can comprise an AR coating and/or a filter coating. In one non-limiting example, an AR coating can be applied to (e.g., deposited over) the first face 204a of the window wafer 204. In some embodiments, the window wafer 204 is a DSP wafer that includes an AR surface, for example an AR coating on at least one of the first face 204a, the second face 204b, or a combination thereof. In another non-limiting example, a filter coating can be applied to (e.g., deposited over) at least one of the faces 204a, 204b, or a combination thereof in a 2-D array of rectangles to improve the quality of the laser beam LB emitted by the EELD 210. In yet another non-limiting example, the AR surface can comprise a high LIDT coating. A high LIDT, such as that of the high LIDT coating, may comprise a LIDT greater than 1 J/cm² for pulsed lasers at any given wavelength or over a wavelength range. As an example, a high LIDT may be at least 10 J/cm² for a near-infrared laser beam. For higher power laser beams emitted a short distance from the window wafer 204, it is beneficial for the window wafer 204 to include a high laser-induced damage threshold (LIDT). The high LIDT coatings can be created by mitigating defects in the coatings.

In another example, one or more AR surfaces can comprise a textured surface configured to form an antireflective topography. In these embodiments, at least one of the first face 204a, second face 204b, or a combination thereof includes a textured surface for antireflection. The textured surface can provide a high LIDT, which may comprise a LIDT greater than 1 J/cm² for pulsed lasers at any given wavelength or over a wavelength range. In some embodiments, the textured surface can comprise textured areas that may be formed in a matrix of discrete rectangular areas. In one non-limiting example, the textured surface comprises a “motheye” topography. The texturing can be accomplished by wet or dry etching processes performed through a mask defined by lithography.

In still another example, one face 204a, 204b of the window wafer 204 can have a textured surface for antireflection while the opposing face 204a, 204b can be textured to form a lens (e.g., a Fresnel lens or a modern metalens). In some embodiments, the monochromatic nature of the laser beam LB emitted by the EELD 210 can enhance compatibility with metalenses. Alternatively, in other embodiments, the second face 204b, which is disposed distal from the EELD 210 and forms part of the exterior (e.g., exterior face), can be bonded with an array of lenses or microlenses. In these embodiments, if the added lens has the same refractive index as the material comprising the window wafer 204, then reflection losses can be minimized.

In an example, imprinted lenses can be applied to the window wafer 204 prior to wafer bonding as long as the imprinted lenses can endure the temperature and pressure of wafer bonding. Otherwise, the imprinted microlenses can be applied to the window wafer 204 after the wafer bonding and prior to the process of singulation.

In some embodiments, the cavity wafer 206 is configured to have a substantially similar (e.g., matching) coefficient of thermal expansion (CTE) as the window wafer 204. A technique to achieve substantially similar CTEs (hereinafter referred to as CTE matching) is by using the same material in the wafers 204, 206 (e.g., composition matching). As an example, the cavity wafer 206 can be comprised of the same material as the window wafer 204 to achieve CTE matching. In another embodiment, CTE matching can be achieved using alternative materials for the cavity wafer 206. In one non-limiting example, the cap 202 can comprise an Invar cavity wafer 206 and the window wafer 204 can comprise silicon or Borofloat 33 glass. In another non-limiting example, the cap 202 can comprise a silicon cavity wafer 206 and the window wafer 204 can comprise Borofloat 33 glass. In yet another non-limiting example, the cap 202 can comprise a Kovar cavity wafer 206 and the window wafer 204 can comprise sapphire. It is to be appreciated that the cavity wafer 206 can be Invar, silicon, Kovar, fused silica, glass, sapphire, among others. Further, it is to be appreciated that the window wafer 204 can be, but is not limited to, silicon, fused silica, glass, sapphire, Borofloat 33 glass, among others.

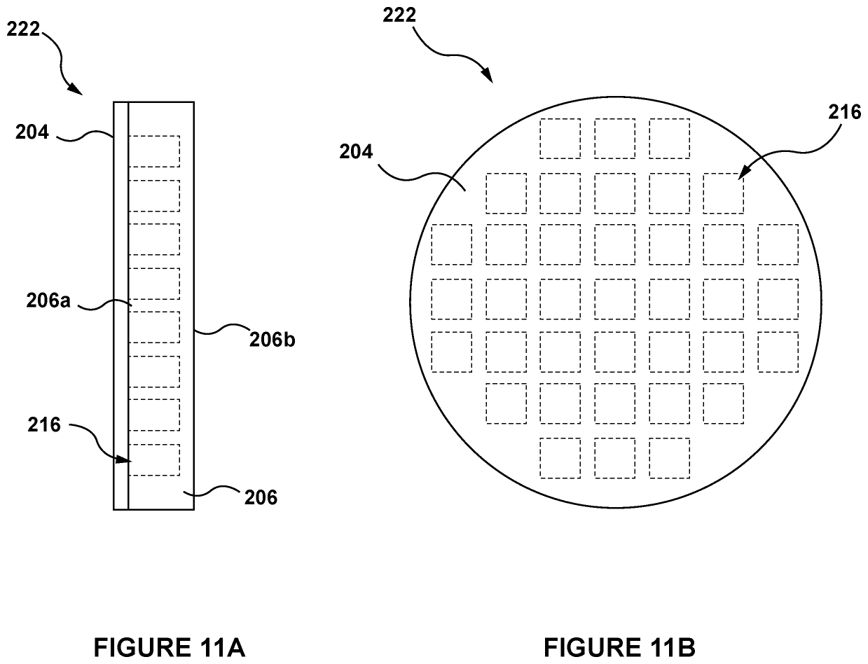

FIGS. 11A and 11B show bonding of the window wafer 204 to the cavity wafer 206. It is to be appreciated that various types of bonding can be utilized to bond the window wafer 204 to the first face 206a of the cavity wafer 206. The type of bonding to bond the cavity wafer 206 to the window wafer 204 can be selected with sound engineering judgment without departing from the scope of the subject innovation.

For example, hermetic bonding can be used to bond the window wafer 204 to the first face 206a of the spacer wafer 206. The hermetic bonding can be accomplished in a vacuum wafer bonder using methods such as, but not limited to, solder bonding, direct bonding, anodic bonding, and the like. In a non-limiting example, solder bonding can be achieved by coating one face of the wafer (e.g., window wafer 204) with a solder (e.g., AuSn, CuSn, AuGe, AuSi, among others) and metallizing the matching areas on the opposite wafer (e.g., cavity wafer 206) with a solderable metal. In another non-limiting example, anodic bonding can be directly achieved by bonding an alkali-containing glass wafer (e.g., window wafer 204) to a Si or other glass wafer (e.g., cavity wafer 206). In another non-limiting example, a thin film of borosilicate glass can be deposited on a glass or metal wafer to enable anodic bonding. In yet another non-limiting example, direct bonding, also known as fusion bonding, can be performed at a temperature of approximately 400° C. to bond the window wafer 204 to the first face 206a of the cavity wafer 206. Direct bonding is sensitive to the surface roughness of the wafers because it relies on weak physical forces (e.g., the formation of covalent bonds between Si and silicon dioxide (SiO₂) substrates) that vanish at distances of just a few nanometers (nm). As such, the wafer surfaces have to be very smooth for fusion bonding; for example, the wafers may have surface roughness values (Ra) below 0.3 nm-0.5 nm.

In other embodiments, wafer bonding is incorporated to bond the window wafer 204 to the first face 206a of the cavity wafer 206. In some embodiments, the wafer bonding can be performed at room temperature using a laser. It is to be appreciated that bonding a window wafer to a cavity wafer via laser bonding offers many advantages. First, the laser bonding can be performed at low temperature, such as at room temperature, which advantageously mitigates heat-related damage to any previously-formed optical coatings and other active layers. Thus, the window wafer 204 and/or cavity wafer 206 can be coated before laser treatment. Further, laser bonding provides a minimal heat load because the heat-affected zone (i.e., the laser treatment zone) is very small—for example, only a few micrometers. Beneficially, the low heat allows for the use of less bulk/material and, thus, permits the use of thinner materials. Second, laser bonding provides for direct bonding between the cavity wafer and window wafer without requiring additive materials, such as adhesives, and without leaving a gap between the window wafer (e.g., window wafer 204) and the cavity wafer (e.g., cavity wafer 206). It is to be appreciated that no adhesives means no outgassing and direct laser bonding does not require metal or metal-seed layers for bonding. In a non-limiting example, direct laser bonding for wafer-level chip scale packaging permits glass-to-glass sealing.

It is to be appreciated that laser bonding is a wafer-level process that enables highly efficient and scalable device manufacturing. It is to be appreciated laser bonding helps to optimize the coefficient of thermal expansion (CTE) and CTE matching between wafer materials enables a strong, hermetic seal between the materials. In some non-limiting examples, laser bonding may be used to bond a glass cavity wafer to a glass window wafer, or a glass cavity wafer to a Si window wafer. It is conceivable that infrared (IR) lasers may be used as the laser source to bond a Si cavity wafer to a Si window wafer.

In some embodiments, the wafers 204, 206 can be bonded together without forming a hermetic bond. In these embodiments, an organic adhesive can be used to bond the cavity wafer 206 to the window wafer 204. Preferably, the adhesive has minimal (e.g., where low outgassing adhesive is defined by NASA and ASTM E595) outgassing during B-staging and cure, but this is not required. It is to be appreciated that a cost reduction may be provided by not using hermetic bonding to bond the wafers 204, 206 because anodic bonding and solder bonding require sophisticated wafer bonders, typically done under vacuum (e.g., costly process), whereas glue bonding can be done on a hot plate in air.

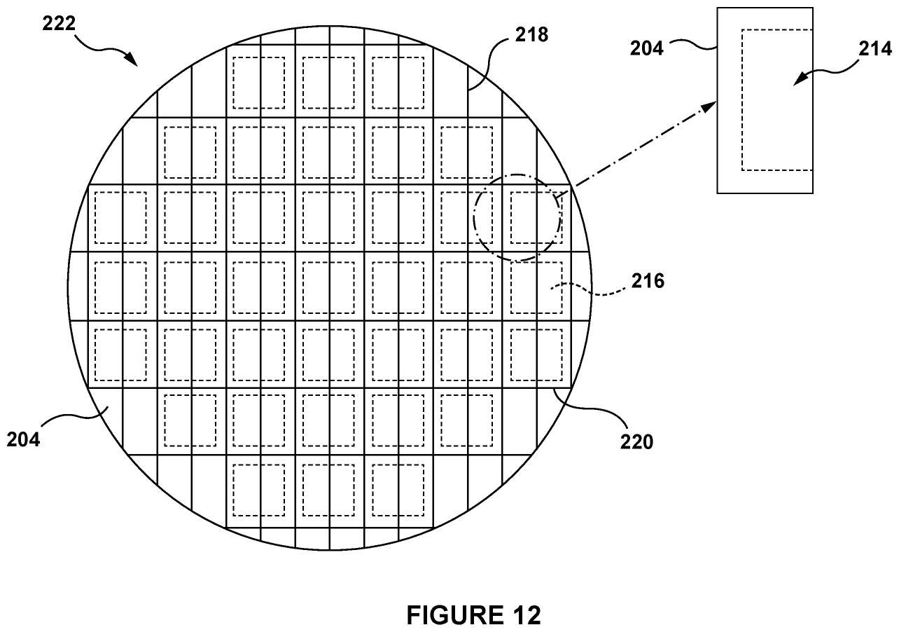

Referring now to FIGS. 11A-11B and 12, an example of a bonded wafer 222 (e.g., a stack of bonded wafers) is illustrated that includes two wafers—the window wafer 204 bonded to the first face 206a of the cavity wafer 206. The bonded wafer 222 can be oriented for dicing or sawing of the bonded wafer 222 into individual parts in order to produce caps 202 in a process referred to as singulation.

Prior to dicing/sawing, the bonded wafer 222 is positioned with the DSP window wafer 204 as the top surface. The bonded wafer 222 can then be diced along cut lines 218 and 220 to produce the caps 202 by singulation. It is to be appreciated that the bonded wafer 222 can be diced along cut lines 218 and 220 at the same time or one at a time (e.g., sequentially).

FIG. 12 depicts cut lines 218 and 220 which extend through the bonded wafer 222. The cut lines 218 can be arranged to extend through the array of cavities 216 (e.g., intersecting the cavities 216) such that cutting downwards along the cut lines 218 cuts through the array of cavities 216 within the bonded wafer 222 to form cavities 214. In some examples, the array of cavities 216 are cut into sections of substantially equal dimensions which may provide substantially uniform cavities 214. The cut lines 220 can be arranged orthogonal to the cut lines 218. The cut lines 220 can be arranged to extend between the array of cavities 216 without intersecting the array of cavities 216 such that cutting downwards along the cut lines 220 cuts through two layers of wafer material. For example, dicing along cut lines 220 cuts through cavity wafer walls that define the array of cavities 216 without the path of the cut lines 220 intersecting with the array of cavities 216.

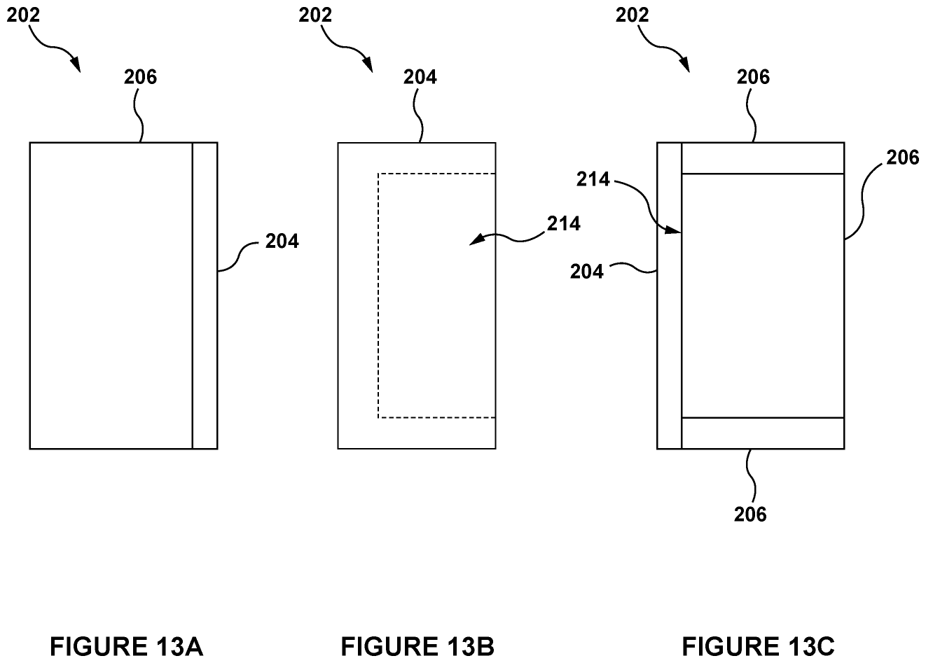

Dicing along cut lines 218 and 220, produces the caps 202 shown in FIGS. 13A through 13C. In some implementations, the cut lines 218 extend through an array of rectangular cavities 216 such that dicing along the cut lines 218 separates the larger rectangular cavities 216 into two smaller rectangular openings that are substantially equal in size. In some implementations, the bonded wafer 222 can be diced along cut lines 218, 220 using a diamond saw, water jet, ultrasonic jet, or other suitable method. In some embodiments, the bonded wafer 222 can be either waxed down or on blue tape adhesive to hold the bonded wafer 222 during dicing.

Referring still to FIGS. 13A-13C, there is an example embodiment of a two wafer (e.g., two-layer) cap 202 formed by singulation. In this example, the cap 202 comprises four sidewalls and a lid or roof. In particular, the window wafer 204 forms one sidewall of the cap 202, and the cavity wafer 206 forms three sidewalls and the roof of the cap 202. The window wafer 204 and the cavity wafer 206 together define an uncovered cavity 214 (e.g., open cavity) in the cap 202. In some embodiments, singulation results in a cap 202 in which one of the four sidewalls of each cap 202 comprises DSP window wafer.

Although not shown, the cap 202 formed from dicing of the bonded wafer 222 can comprise a lip (e.g., similar to 124 of FIG. 7B) that results from singulation. In some embodiments, the surface of the lip can be grinded and/or polished to improve flatness and reduce surface roughness.

Although not shown, in some embodiments, the lip can be metallized, such as by forming a metal surface (e.g., similar to 126 in FIG. 7C) on the lip, to facilitate bonding of the lip to a metal surface (e.g., similar to 128 in FIGS. 8A-8B) on the submount 212. In some embodiments, the composition of the metal surface can be selected to be compatible with (e.g., matching) the metal surface on the submount 212. In an embodiment, metallizing the lip can be performed by use of a paint or ink designed to form a hermetic, solderable metal surface on the lip. Since the lip of each cap 202 is not defined until after singulation, metallization of the lip can be done in a way that is compatible with mass production of caps 202. In some implementations, these paints or inks may require drying and firing steps in order to maximize the bond strength between the metal in the paint/ink and the material (e.g., glass, sapphire, silicon, among others) of the lip. Paints and inks are typically filled with metal particles or flakes such as Ni or Ag. The paint or ink can be applied to large quantities of these caps 202 using automated machines for pad printing or dip coating.

In some embodiments, the lip of the cap 202 can be coated by a physical vapor deposition (PVD) process (e.g., sputtering or evaporation) with a thin film metallization stack if the ceiling of the cap 202 can be masked by a metal or photoresist. In these embodiments, the thin film metallization stack can comprise Gelot metallization of Materion Balzers Optics. It is to be appreciated that such a thin film metallization can enhance compatibility with solders.

Referring back to FIG. 9, there is a cross-sectional view of the cap 202 enclosing the EELD 210 on a submount 212. In some embodiments, the cap 202 can include a metal surface on the bottom lip of the cap 202. When the cap 202 is mounted on the submount 212 the metal surface can engage a complimentary metal surface on the submount 212. In some embodiments, the submount 212 is made of ceramic. In some examples, the EELD 210 can be bonded to the ceramic submount 212 with vias to the backside (not shown). In an embodiment, a DSP metal spacer can be interposed between the EELD 210 and the submount 212 to provide vertical distance for the laser beam LB to fan out from the edge of the EELD chip before reaching the sidewall (e.g., first face 204a of the window wafer 204 in FIG. 9). It is to be appreciated the semiconductor package 200 provided herein is smaller in footprint and volume, and is compatible with fully automated (robot) assembly. Additionally, the semiconductor package 200 provided herein permits the cap 202 to be mounted on a co-fired AIN submount 212 which provides better thermal performance than conventional semiconductor packages.

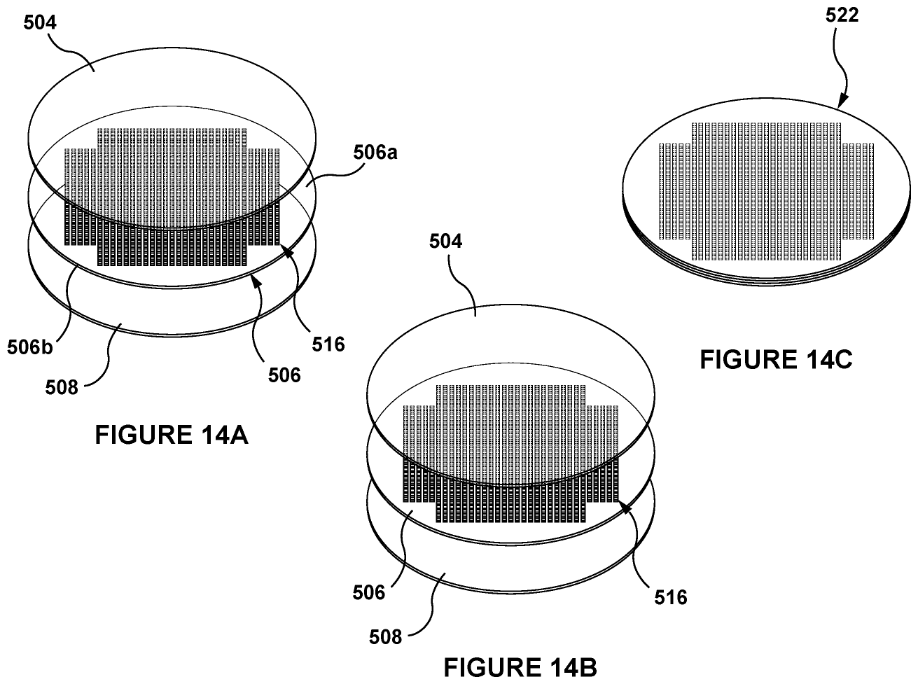

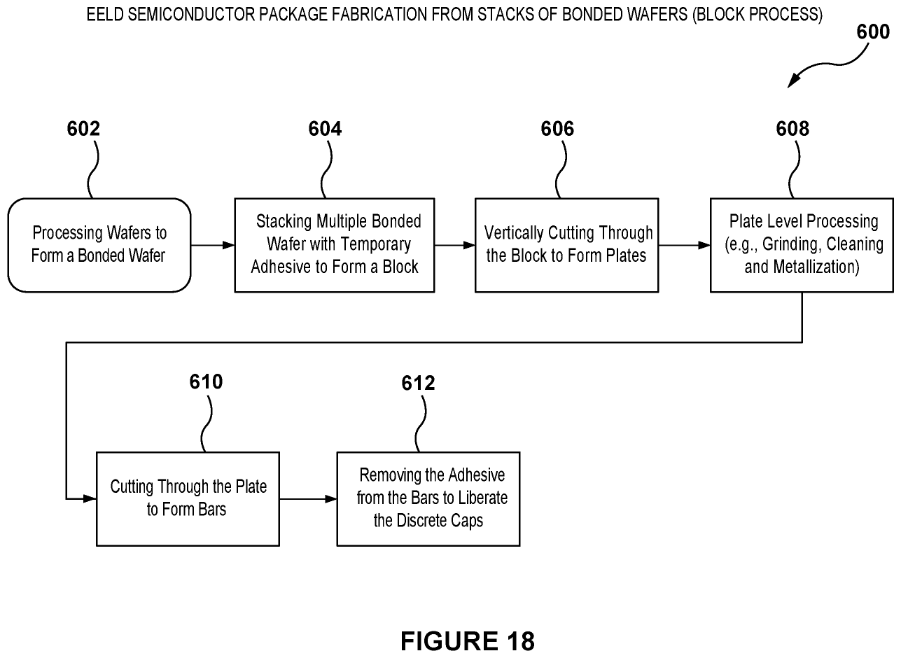

Following is a description of an example implementation of a method 600 (FIG. 18 with reference to FIGS. 14A-17) by which the exemplary three-wafer cap 502 of FIG. 17, as well as other caps (e.g., the two-wafer cap 202 of FIGS. 13A-13C), may be manufactured reliably and efficiently in volume quantities using the techniques disclosed herein. The method 600 will be described with reference to FIGS. 14A-17 which illustrate various stages in the fabrication of the cap 502.

Referring now to FIGS. 14A-18, the method 600 begins at flowchart step 602 with the processing of wafers to form a bonded wafer. In some implementations, the processed wafers are bonded to form a bonded wafer sandwich 522 comprising three wafers. The wafers can be processed by forming an AR surface on at least one face of a window wafer and forming a plurality of through-holes in a spacer wafer as described above with respect to FIGS. 2-8B. In other implementations, the processed wafers are bonded to form a bonded wafer sandwich comprising two wafers (e.g., 222 of FIGS. 11A-11B). The wafers can be processed by forming an AR surface on at least one face of a window wafer and forming an array of cavities in a cavity wafer as described above with respect to FIGS. 9-13C. As illustrated in FIGS. 14A-14C, bonding of the processed wafers can comprise bonding first and second window wafers 504, 508 to opposing faces 506a, 506b of a spacer wafer 506 such that the spacer wafer 506 is sandwiched between the first and second window wafers 504, 508. The spacer wafer 506 is perforated with a plurality of through-holes 516 extending from a first face 506a of the spacer wafer 506 to an opposing second face 506b of the spacer wafer 506. In the embodiment of FIG. 14A, the first and second window wafers 504, 508 are made of glass and the spacer wafer 506 is made of glass. In the embodiment of FIG. 14B, the first and second window wafers 504, 508 are made of glass and the spacer wafer 506 is made of silicon. But, the window wafers and spacer wafer are not limited to these materials and can comprise other materials described above. FIG. 14C shows bonded wafer sandwich 522 in which the spacer wafer 506 is sandwiched between the first and second window wafers 504, 508 and bonded to the first and second window wafers 504, 508 by a bonding process including, but not limited to, anodic bonding, solder bonding, direct bonding, laser bonding, among others. In some examples, the spacer wafer 506 can be bonded to the first and second window wafers 504, 508 by fusion bonding, laser bonding, or eutectic bonding.

Alternatively, processing the wafers to form a bonded wafer can comprise bonding a window wafer to a cavity wafer to form a two-layer bonded wafer (e.g., 222 of FIG. 11A). In this example, the bonded wafer comprises two wafers that are bonded together as described above with respect to FIGS. 9-13C.

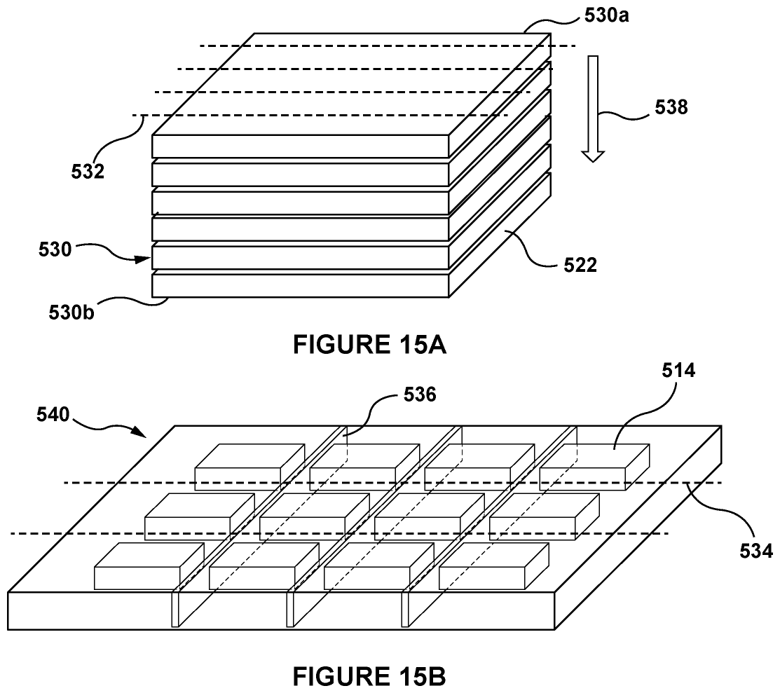

At 604, is the step of stacking multiple bonded wafers to form a block. In some implementations, multiple bonded wafer sandwiches are stacked to form a block. Stacking multiple bonded wafer sandwiches together to form a block facilitates high volume manufacturing. In FIG. 15A, there is an example block 530 comprising six rectangular bonded wafer sandwiches 522. It will be appreciated that the block of this method 600 is not limited to any particular shape and/or number of bonded wafer sandwiches and the FIGURES are used for the purpose of explaining the principles of the method 600. In some embodiments, a temporary adhesive (e.g., 536 of FIG. 15B), or glue, can be used to hold the bonded wafer sandwiches 522 together so the block 530 is stable and retains its form/structure. It is important to establish precise alignment of the cavities between the stack of bonded wafer sandwiches 522 before the temporary adhesive is cured. The temporary adhesive can be selected to withstand temperatures in excess of 200° C. One example of a high temperature temporary adhesive (e.g., capable of withstanding temperatures in excess of 200° C.) is a fugitive adhesive.

At 606, is the step of cutting through the block 530 to form plates. FIG. 15A depicts vertical cutting paths, or saw paths 532, which extend through the bonded wafer sandwiches 522 of the block 530. Cutting in the direction of arrow 538 from a top 530a of the block 530 to the bottom 530b of the block 530 along the saw paths 532 cuts through each bonded wafer sandwich 522 and cuts through the through-holes 516 within each bonded wafer sandwich 522 to form cavities (e.g., 514 of FIG. 15B) in the resulting plates (e.g., 540 of FIG. 15B). In some examples, the through-holes are cut into two portions of substantially similar dimensions. In one example, cutting along the saw paths 532 can be performed with a multi-wire saw (MWS) which makes it possible to perform multiple cuts of the block 530 at the same time.

At 608, is the step of processing the plates. In FIG. 15B, there is an example of a plate 540 resulting from sawing along saw paths 532 in which cavities 514 and the lips (e.g., 124 of FIG. 7B) surrounding the cavities 514 are exposed at the surface of the plate 540. This permits various processing steps to be performed on the plate 540. In another example, the processing includes grinding of the lips of the plate 540 to create a substantially flat surface. Grinding of the lips of the plate 540 can be performed to remove chatter marks left behind by sawing. In one example, the processing includes performing a soft ultrasonic cleaning of the plate 540. In still another example, the processing includes metallization of the lips of the plate 540, preferably after the step of grinding. In some embodiments, the window wafer sidewall can be masked to mitigate application of metal coating to the window wafer sidewall. Methods of metallizing the lips include physical vapor deposition (PVD) (e.g., sputtering and evaporation), screen printing, ink dipping, pad printing, among others.

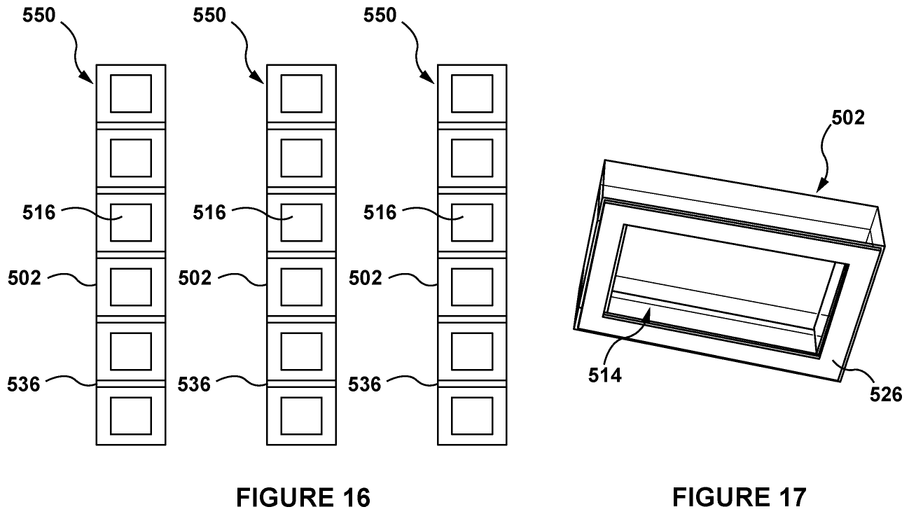

At 610, is the step of cutting through the plates to form bars. FIG. 15B depicts cutting paths, or saw paths 534, which extend through the plate 540. Cutting downward from a top of the plate 540 to a bottom of the plate 540 along saw paths 534 produces a plurality of bars 550, as shown in FIG. 16. In one example, cutting along the saw paths 534 can be performed with a MWS which makes it possible to perform multiple cuts of the plate 540 at the same time.

At 612, is the step of removing the temporary adhesive from the bars 550 to liberate the caps 502. FIG. 16 shows bars 550 that each include a plurality of caps 502 which are held together by the temporary adhesive 536. In some implementations, the temporary adhesive 536 can be removed by exposing the bars 550 to solvent. In one example, the bars 550 can be placed in solvent to remove the temporary adhesive and liberate the caps 502 from the bars 550. FIG. 17 shows a cap 502 that includes a cavity 514 and a metal surface 526 on a bottom lip of the cap 502.

It will be appreciated that this method 600 permits metallization of all the lips of the plate 540 at the same time which eliminates the need to metallize the lip of each cap one at a time. A cap for a conventional EELD semiconductor package may have an exterior footprint as small as 3 mm×3 mm, so metallizing caps one at a time is slow and expensive. The method 600 discloses herein provides plates that includes cavities and lips facing upward and exposed thereby facilitating masking and metallization of all the lips on the plate at once. By facilitating metallization of all lips on the plate at one time, the method 600 saves time and money over convention techniques for manufacturing EELD semiconductor packages. Moreover, the method 600 provides for dissolving the temporary adhesive to liberate the caps that already include metallized lips. Thus, there is no handling/flipping of caps 502 until the parts are finished according to the method 600.

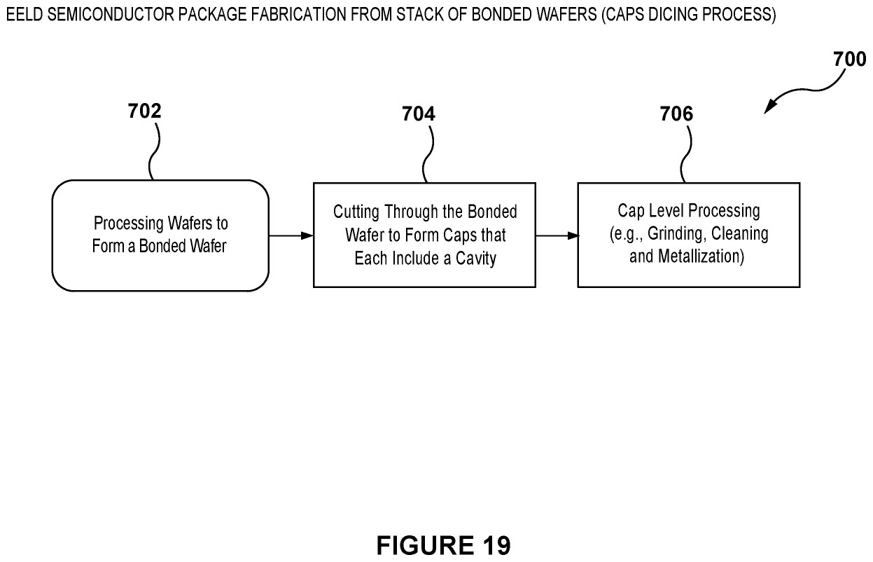

Following is a description of an example implementation of a method 700, as shown in FIG. 19, by which a three-wafer cap (e.g., 102 of FIGS. 6A-7C) as well as a two-wafer cap (e.g., 202 of FIGS. 13A-13C) may be manufactured reliably using the techniques disclosed herein. The method 700 will be described with reference to FIGS. 4A-7C and 11A-13C which illustrate various stages in the fabrication of a cap (e.g., 102 of FIGS. 6A-7C or 202 of FIGS. 13A-13C).

Referring now to FIGS. 4A-7C, the method 700 begins at flowchart step 702 with the processing of wafers to form a bonded wafer. In some implementations, the processed wafers are bonded to form a bonded wafer sandwich comprising three wafers (e.g., 122 of FIGS. 4A-4B). The wafers can be processed by forming an AR surface on at least one face of a window wafer and forming a plurality of through-holes in a spacer wafer as described above with respect to FIGS. 2-8. As an example, FIGS. 4A-4B show bonding of the processed wafers to form the bonded wafer sandwich can comprise bonding first and second window wafers 104, 108 to opposing faces 106a, 106b of a spacer wafer 106 containing the plurality of through-holes 116 such that the spacer wafer 106 is sandwiched between the first and second window wafers 104, 108 and bonded to the first and second window wafers 104, 108 by a bonding process including, but not limited to, anodic bonding, solder bonding, direct bonding, laser bonding, among others. In some examples, the spacer wafer 506 can be bonded to the first and second window wafers 504, 508 by fusion bonding, laser bonding, or eutectic bonding.

In other implementations, the processed wafers are bonded to form a bonded wafer sandwich comprising two wafers (e.g., 222 of FIGS. 11A-11B). The wafers can be processed by forming an AR surface on at least one face of a window wafer and forming an array of cavities in a cavity wafer as described above with respect to FIGS. 9-13C. As an example, FIGS. 11A-11B show bonding of the processed wafers to form the bonded wafer sandwich can comprise bonding window wafer 204 to a face 206a of a cavity wafer 206 containing an array of cavities 216 such that the cavity wafer 206 is bonded to the window wafer 204 by a bonding process including, but not limited to, anodic bonding, solder bonding, direct bonding, laser bonding, among others. In some examples, the cavity wafer 206 can be bonded to the window wafer 204 by fusion bonding, laser bonding, or eutectic bonding.

At 704, is the step of cutting through the bonded wafer sandwich as shown in FIGS. 5 and 12 to form caps (e.g., 102 of FIGS. 6A-7C or 202 of FIGS. 13A-13C) that each include a cavity (e.g., 114 of FIGS. 6A-7C or 214 of FIGS. 13A-13C). The bonded wafer sandwich comprising three wafers 122 can be diced along cut lines 118 to cut through the through-holes 116 within the bonded wafer sandwich 122 and along cut lines 120 to cut through spacer wafer walls defining the through-holes to produce the caps 102 by singulation. It is to be appreciated that the bonded wafer sandwich 122 can be diced along cut lines 118 and 120 at the same time or one at a time (e.g., sequentially). In some implementations, the bonded wafer 122 is positioned with the DSP window wafer as the top surface prior to dicing/sawing the bonded wafer sandwich 122 along cut lines 118, 120 using a diamond saw, water jet, ultrasonic jet, or other suitable method.

The bonded wafer sandwich comprising two wafers 222 can be diced along cut lines 218 to cut through the array of cavities 216 within the bonded wafer sandwich 222 and along cut lines 220 to cut through cavity wafer walls defining the array of cavities to produce the caps 202 by singulation. It is to be appreciated that the bonded wafer 222 can be diced along cut lines 218 and 220 at the same time or one at a time (e.g., sequentially). In some implementations, the bonded wafer 222 is positioned with the DSP window wafer as the top surface prior to dicing/sawing the bonded wafer sandwich 222 along cut lines 218, 220 using a diamond saw, water jet, ultrasonic jet, or other suitable method.

At 706, the cap (e.g., 102 of FIGS. 6A-7C or 202 of FIGS. 13A-13C) can be processed and metallized. In a non-limiting example, the cap can be placed on a plate for further processing. In some embodiments, the cap can comprise a lip that results from singulation and the surface of the lip can be grinded and/or polished to improve flatness and reduce surface roughness. In some embodiments, the lip can be metallized, such as by forming a metal surface on the lip, to facilitate bonding of the lip to a metal surface on the submount. In an embodiment, metallizing the lip can be performed by use of a paint or ink designed to form a hermetic, solderable metal surface on the lip. In another embodiment, the lip of the cap can be coated by a physical vapor deposition (PVD) process (e.g., sputtering or evaporation) with a thin film metallization stack if the ceiling of the cap can be masked by a metal or photoresist.

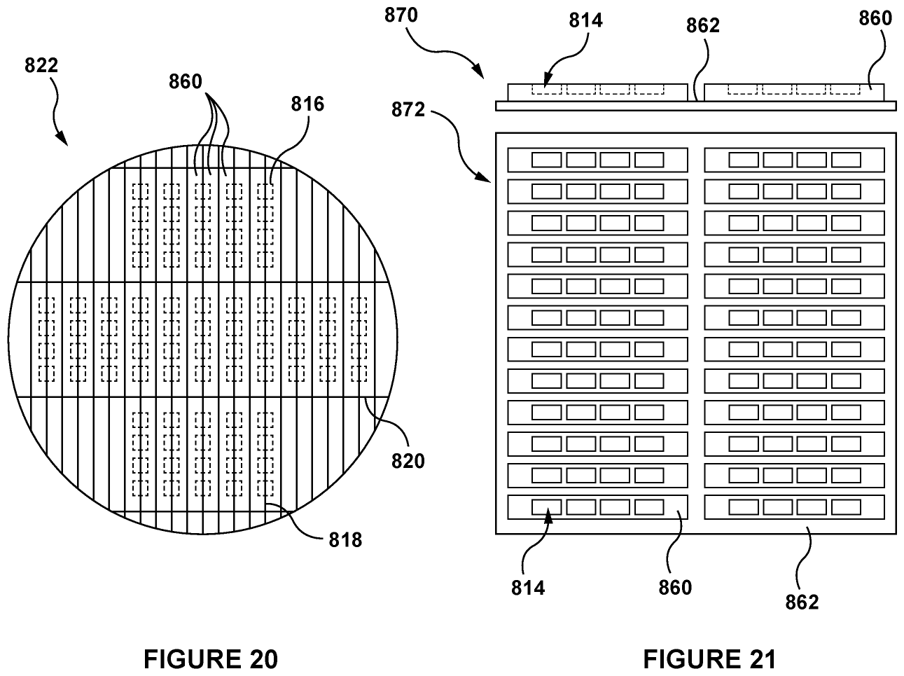

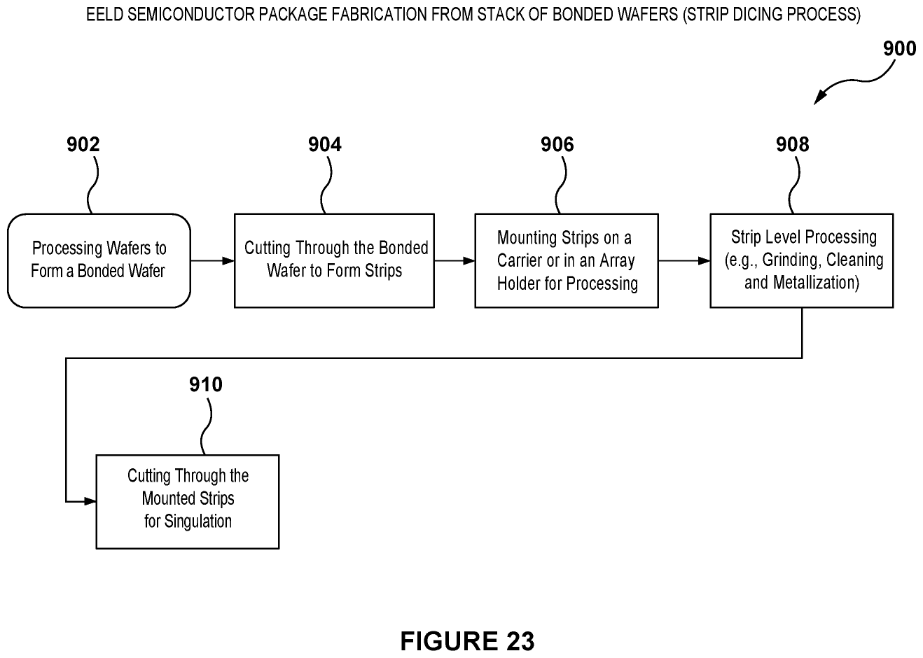

Following is a description of an example implementation of a method 900, as shown in FIG. 23, by which a multi-wafer cap (e.g., three-wafer cap 102 of FIGS. 7A-7C or two-wafer cap 202 of FIGS. 13A-13C) may be manufactured reliably and efficiently in volume quantities using the techniques disclosed herein. The method 900 will be described with reference to FIGS. 20-22, in view of FIGS. 4A-7C and 11A-13C which illustrate various stages in the fabrication of a cap (e.g., 102 of FIGS. 7A-7C or 202 of FIGS. 13A-13C), as well as method 700.

The method 900 begins at flowchart step 902 with the processing of wafers to form a bonded wafer, such as the bonded wafer sandwich 822 shown in FIG. 20. The bonded wafer sandwich 822 comprises multiple wafers such as, for example, two wafers (e.g., 222 of FIGS. 11A-11B) or three wafers (e.g., 122 of FIGS. 4A-4B). The processing of wafers to form a bonded wafer sandwich, such as bonded wafer sandwich 822, is described above in method 700 and, for the sake of brevity, will not be repeated.

At 904, is the step of cutting through the bonded wafer sandwich 822 to form strips 860 that include a plurality of cavities 814, as shown in FIGS. 20-21. In some embodiments, the bonded wafer sandwich 822 is a three-wafer bonded wafer sandwich (e.g., 122 of FIG. 4A) that can be diced along cut lines 818 to cut through the through-holes (e.g., 816 in FIG. 20) within the bonded wafer sandwich 822 and along cut lines 820 to cut through select spacer wafer walls defining the through-holes (e.g., 816 in FIG. 20) to produce strips 860. In other embodiments, the bonded wafer sandwich 822 is a two-wafer bonded wafer sandwich (e.g., 222 of FIG. 11A) that can be diced along cut lines 818 to cut through the array of cavities (e.g., 816 in FIG. 20) within the bonded wafer sandwich 822 and along cut lines 820 to cut through select cavity wafer walls defining the array of cavities (e.g., 816 in FIG. 20) to produce strips 860 containing multiple cavities 814. The strips 860 are not limited to any specific number of cavities 814. In a non-limiting example, the strips 860 include four cavities 814. In another non-limiting example, the strips 860 include five cavities 814.

It is to be appreciated that the bonded wafer sandwich 822 can be diced along cut lines 818 and 820 at the same time or one at a time (e.g., sequentially). In some implementations, the bonded wafer 822 is positioned with the DSP window wafer as the top surface prior to dicing/sawing the bonded wafer sandwich 822 along cut lines 818, 820 using a diamond saw, water jet, ultrasonic jet, or other suitable method.

At 906, is the step of mounting the strips to a carrier or in an array holder for further processing. FIG. 21 illustrates strips 860 mounted on a carrier 862, such as a plate, from a side view 870 and from a plan view 872. In this particular embodiment, the strips 860 each include four cavities 814 which reduces the time and cost of picking and placing individual caps for processing, such as described above in the method 700.

At 908, the strips 860, which are mounted on a carrier 862 or in an array holder, can be processed and metallized. In some embodiments, the strips can comprise a lip and the surface of the lip can be grinded and/or polished to improve flatness and reduce surface roughness. In some embodiments, the lip can be metallized, such as by forming a metal surface on the lip, to facilitate bonding of the lip to a metal surface on the submount at a later stage after singulation. In an embodiment, metallizing the lip can be performed by use of a paint or ink designed to form a hermetic, solderable metal surface on the lip. In another embodiment, the lip can be coated by a physical vapor deposition (PVD) process (e.g., sputtering or evaporation) with a thin film metallization stack if the ceiling of the strip can be masked by a metal or photoresist.

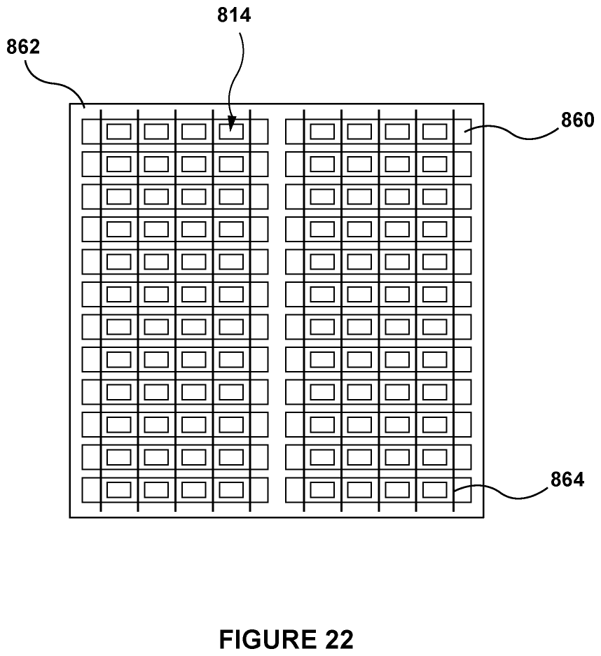

At 910, is the step of cutting through the mounted strips 860 along cut lines 864, as shown in FIG. 22. Cutting or dicing the mounted strips 860 along the cut lines 864 produces caps (e.g., 102 of FIGS. 6A-7C or 202 of FIGS. 13A-13C) that each include a cavity 814 by singulation of the strips 860. It is to be appreciated that the mounted strips 860 can be diced along cut lines 864 at the same time or one at a time (e.g., sequentially) using a diamond saw, water jet, ultrasonic jet, or other suitable method.

The following examples are further illustrative of the present disclosure. The semiconductor packages and methods of forming said semiconductor packages and components thereof (e.g., the cap) are presented as being typical, and various modifications can be derived in view of the foregoing disclosure within the scope of the disclosure.

In some embodiments, provided is a semiconductor package comprising: a cap comprising: a first window wafer comprising a first face and opposing second face, wherein the first face and second face are mutually parallel, and wherein the first face and/or second face includes an antireflective surface; a second window wafer comprising a first face and opposing second face; and a spacer wafer that is perforated with a plurality of through-holes extending from a first face of the spacer wafer to an opposing second face of the spacer wafer, wherein the spacer wafer is disposed between the first window wafer and the second window wafer with the first window wafer bonded to the first face of the spacer wafer and the second window wafer bonded to the second face of the spacer wafer, wherein the first window wafer, second window wafer, and spacer wafer together define a cavity in the cap; and an edge-emitting laser diode disposed on a submount and configured to direct a laser beam at normal incidence to the first face of the first window wafer, wherein the cap is mounted on the submount with the edge-emitting laser diode enclosed in the cavity.

In one embodiment of the semiconductor package, the antireflective surface comprises an antireflective coating, a filter coating, or a textured surface configured to form an antireflective topography. In a particular embodiment, the textured surface comprises a motheye topography in which textured areas are formed in a matrix of discrete rectangular areas.

In another embodiment of the semiconductor package, the first face of the first window wafer is disposed proximal to the edge-emitting laser diode and includes the antireflective surface. In a particular embodiment, the second face of the first window wafer is disposed distal to the edge-emitting laser diode and is bonded to an array of lenses or microlenses.

In yet another embodiment of the semiconductor package, the first window wafer and/or the second window wafer is a dual side polished wafer.

In still another embodiment of the semiconductor package, the first window wafer comprises DSP fused silica, glass, sapphire, Borofloat 33 glass, or silicon.

In another embodiment of the semiconductor package, the first and second window wafers each have a thickness of 0.2 mm to 0.8 mm and the spacer wafer has a thickness of 0.5 mm to 3.5 mm.

In yet another embodiment of the semiconductor package, the spacer wafer is configured to have a substantially similar coefficient of thermal expansion (CTE) as the first and second window wafers. In a particular embodiment, the spacer wafer is comprised of substantially the same material as the first window wafer and/or the second window wafer.

In still another embodiment of the semiconductor package, the first window wafer, second window wafer, and spacer wafer each have a circular shape with a diameter between 150 mm and 200 mm.

In yet another embodiment of the semiconductor package, the spacer wafer comprises Invar, silicon, Kovar, fused silica, glass, or sapphire.

In another embodiment of the semiconductor package, the submount is made of ceramic.

In still another embodiment, the plurality of through-holes are rectangular, triangular, or circular.

In other embodiments, provided is a semiconductor package comprising: a cap comprising: a window wafer comprising a first face and opposing second face, wherein the first face and second face are mutually parallel, and wherein the first face and/or second face includes an antireflective surface; and a cavity wafer that includes an array of cavities extending from a first face of the cavity wafer towards an opposing second face of the cavity wafer and including a bottom, wherein the window wafer is bonded to the first face of the cavity wafer, wherein the window wafer and cavity wafer together define a cavity in the cap; and an edge-emitting laser diode disposed on a submount and configured to direct a laser beam at normal incidence to the first face of the window wafer, wherein the cap is mounted on the submount with the edge-emitting laser diode enclosed in the cavity.

In one embodiment of the semiconductor package, the antireflective surface comprises an antireflective coating, a filter coating, or a textured surface configured to form an antireflective topography. In a particular embodiment, the textured surface comprises a motheye topography in which textured areas are formed in a matrix of discrete rectangular areas.

In another embodiment of the semiconductor package, the first face of the window wafer is disposed proximal to the edge-emitting laser diode and includes the antireflective surface. In a particular embodiment, the second face of the window wafer is disposed distal to the edge-emitting laser diode and is bonded to an array of lenses or microlenses.

In yet another embodiment of the semiconductor package, the window wafer is a dual side polished wafer.

In still another embodiment of the semiconductor package, the window wafer comprises DSP fused silica, glass, sapphire, Borofloat 33 glass, or silicon.

In another embodiment of the semiconductor package, the cavity wafer is configured to have a substantially similar coefficient of thermal expansion (CTE) as the window wafer. In a particular embodiment, the cavity wafer is comprised of substantially the same material as the window wafer.

In yet another embodiment of the semiconductor package, the window wafer and cavity wafer each have a circular shape with a diameter between 150 mm and 200 mm.

In still another embodiment of the semiconductor package, the cavity wafer comprises Invar, silicon, Kovar, fused silica, glass, or sapphire.

In another embodiment of the semiconductor package, the submount is made of ceramic.

In yet another embodiment of the semiconductor package, the window wafer has a thickness of 0.2 mm to 0.8 mm and the cavity wafer has a thickness of 0.5 mm to 3.5 mm.

In still another embodiment of the semiconductor package, the cavities in the array of cavities are rectangular, triangular, or circular.

In some embodiments, provided is a method for manufacturing a cap for use in an EELD semiconductor package, the method comprising: bonding first and second window wafers to opposing faces of a spacer wafer to form a bonded wafer sandwich, wherein the spacer wafer is disposed between the first window wafer and the second window wafer in the bonded wafer sandwich, wherein the spacer wafer is perforated with a plurality of through-holes extending therethrough between the opposing faces of the spacer wafer, wherein a face of the first window wafer and/or the second window wafer includes an antireflective surface; stacking multiple bonded wafer sandwiches on top of one another to form a block, wherein adjacent bonded wafer sandwiches are secured together using an adhesive; cutting through the block to form at least one plate; processing the plate by metallizing lip portions of the plate; cutting through the plate to form bars; and removing the adhesive from the bars to produce caps.

In one embodiment of the method, the first and second window wafers are bonded to the spacer wafer via solder bonding, direct bonding, anodic bonding, laser bonding, or adhesive bonding. In a particular embodiment, the bonding of the first and second window wafers to the spacer wafer is carried out in two successive steps, comprising: bonding the spacer wafer to the first window wafer; and bonding the second window wafer to the spacer wafer.

In another embodiment of the method, the adhesive is a temporary adhesive.

In still another embodiment of the method, cutting through the block to form at least one plate comprises: cutting through the through-holes within each bonded wafer sandwich to form cavities in the at least one plate.

In yet another embodiment of the method, the adhesive is removed by exposing the bars to solvent.

In another embodiment of the method, processing the plate further comprises: cleaning a surface of the plate; and grinding the surface flat prior to metallizing lip portions of the plate.

In some embodiments, provided is a method for manufacturing a cap for use in an EELD semiconductor package, the method comprising: bonding a window wafer to a cavity wafer to form a bonded wafer sandwich, wherein the cavity wafer includes an array of cavities that extend from a first face of the cavity wafer towards an opposing second face of the cavity wafer and include a bottom, wherein a face of the window wafer includes an antireflective surface; stacking multiple bonded wafer sandwiches on top of one another to form a block, wherein adjacent bonded wafer sandwiches are secured together using an adhesive; cutting through the block to form at least one plate; processing the plate by metallizing lip portions of the plate; cutting through the plate to form bars; and removing the adhesive from the bars to produce caps.

In one embodiment of the method, the window wafer is bonded to the cavity wafer via solder bonding, direct bonding, anodic bonding, laser bonding, or adhesive bonding.

In another embodiment of the method, the adhesive is a temporary adhesive.

In still another embodiment of the method, cutting through the block to form at least one plate comprises: cutting through the array of cavities within each bonded wafer sandwich to form cavities in the at least one plate.

In yet another embodiment of the method, the adhesive is removed by exposing the bars to solvent.

In another embodiment, processing the plate further comprises: cleaning a surface of the plate; and grinding the surface flat prior to metallizing lip portions of the plate.

In some embodiments, provided is a method for making a cap for use in an EELD semiconductor package, the method comprising: processing wafers to form a bonded wafer comprising: bonding first and second window wafers to opposing faces of a spacer wafer to form a bonded wafer sandwich, wherein the spacer wafer is disposed between the first window wafer and the second window wafer in the bonded wafer sandwich, wherein the spacer wafer is perforated with a plurality of through-holes extending therethrough between the opposing faces of the spacer wafer, and wherein a face of the first window wafer and/or the second window wafer includes an antireflective surface; cutting through the bonded wafer sandwich to form caps that each include a cavity; and processing the cap by metallizing a lip of the cap.

In one embodiment of the method, the first and second window wafers are bonded to the spacer wafer via solder bonding, direct bonding, anodic bonding, laser bonding, or adhesive bonding.

In another embodiment of the method, cutting through the bonded wafer sandwich comprises: cutting through the through-holes within the bonded wafer sandwich; and cutting through spacer wafer walls defining the through-holes to produce the caps.

In still another embodiment of the method, processing the cap further comprises: cleaning a surface of the cap; and grinding the surface flat prior to metallizing the lip of the cap.

In some embodiments, provided is a method for making a cap for use in an EELD semiconductor package, the method comprising: processing wafers to form a bonded wafer comprising: bonding first and second window wafers to opposing faces of a spacer wafer to form a bonded wafer sandwich, wherein the spacer wafer is disposed between the first window wafer and the second window wafer in the bonded wafer sandwich, wherein the spacer wafer is perforated with a plurality of through-holes extending therethrough between the opposing faces of the spacer wafer, and wherein a face of the first window wafer and/or the second window wafer includes an antireflective surface; cutting through the bonded wafer sandwich to form strips that each include a plurality of cavities; mounting the strips on a carrier or in an array holder; processing the strips by metallizing a lip of each strip; and cutting through the mounted strips to produce caps that each include a cavity.

In one embodiment of the method, the first and second window wafers are bonded to the spacer wafer via solder bonding, direct bonding, anodic bonding, laser bonding, or adhesive bonding.

In another embodiment of the method, cutting through the bonded wafer sandwich comprises: cutting through the through-holes within the bonded wafer sandwich; and selectively cutting through spacer wafer walls defining the through-holes to produce the strips.

In still another embodiment of the method, the strips each include four cavities.

In yet another embodiment of the method, processing the strips further comprises: cleaning a surface of the strips; and grinding the surface flat prior to metallizing the lips of the strips.

In some embodiments, provided is a method for making a cap for use in an EELD semiconductor package, the method comprising: processing wafers to form a bonded wafer comprising: bonding a window wafer to a cavity wafer to form a bonded wafer sandwich, wherein the cavity wafer includes an array of cavities that extend from a first face of the cavity wafer towards an opposing second face of the cavity wafer and include a bottom, wherein a face of the window wafer includes an antireflective surface; cutting through the bonded wafer sandwich to form caps that each include a cavity; and processing the cap by metallizing a lip of the cap.

In one embodiment of this method, the window wafer is bonded to the cavity wafer via solder bonding, direct bonding, anodic bonding, laser bonding, or adhesive bonding.

In another embodiment of the method, cutting through the bonded wafer sandwich comprises: cutting through the array of cavities within the bonded wafer sandwich; and cutting through cavity wafer walls defining the array of cavities to produce the caps.

In yet another embodiment of the method, processing the cap further comprises: cleaning a surface of the cap; and grinding the surface flat prior to metallizing the lip of the cap.

In some embodiments, provided is a method for making a cap for use in an EELD semiconductor package, the method comprising: processing wafers to form a bonded wafer comprising: bonding a window wafer to a cavity wafer to form a bonded wafer sandwich, wherein the cavity wafer includes an array of cavities that extend from a first face of the cavity wafer towards an opposing second face of the cavity wafer and include a bottom, wherein a face of the window wafer includes an antireflective surface; cutting through the bonded wafer sandwich to form strips that each include a plurality of cavities; mounting the strips on a carrier or in an array holder; processing the strips by metallizing a lip of each strip; and cutting through the mounted strips to produce caps that each include a cavity.

In one embodiment of the method, the window wafer is bonded to the cavity wafer via solder bonding, direct bonding, anodic bonding, laser bonding, or adhesive bonding.

In another embodiment of the method, cutting through the bonded wafer sandwich comprises: cutting through the array of cavities within the bonded wafer sandwich; and cutting through cavity wafer walls defining the array of cavities to produce the strips.

In yet another embodiment of the method, the strips each include four cavities.

In still another embodiment of the method, processing the strips further comprises: cleaning a surface of the strips; and grinding the surface flat prior to metallizing the lip of each strip.

While the embodiments discussed herein have been related to the systems, devices, and methods discussed above, these embodiments are intended to be exemplary and are not intended to limit the applicability of these embodiments to only those discussions set forth herein. The embodiments and discussions herein can be readily incorporated into any of these systems and methodologies by those of skill in the art.

The above examples are merely illustrative of several possible embodiments of various aspects of the present innovation, wherein equivalent alterations and/or modifications will occur to others skilled in the art upon reading and understanding this specification and the annexed drawings. In particular regard to the various functions performed by the above described components (assemblies, devices, systems, circuits, and the like), the terms (including a reference to a “means”) used to describe such components are intended to correspond, unless otherwise indicated, to any component, or combinations thereof, which performs the specified function of the described component (e.g., that is functionally equivalent), even though not structurally equivalent to the disclosed structure which performs the function in the illustrated implementations of the innovation. In addition although a particular feature of the innovation may have been disclosed with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising.”

This written description uses examples to disclose the innovation, including the best mode, and also to enable one of ordinary skill in the art to practice the innovation, including making and using any devices or systems and performing any incorporated methods. The patentable scope of the innovation is defined by the claims, and may include other examples that occur to those skilled in the art. Such other examples are intended to be within the scope of the claims if they have structural elements that are not different from the literal language of the claims, or if they include equivalent structural elements with insubstantial differences from the literal language of the claims.

In the specification and claims, reference will be made to a number of terms that have the following meanings. The singular forms “a”, “an” and “the” include plural referents unless the context clearly dictates otherwise. Approximating language, as used herein throughout the specification and claims, may be applied to modify a quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Moreover, unless specifically stated otherwise, a use of the terms “first,” “second,” etc., do not denote an order or importance, but rather the terms “first,” “second,” etc., are used to distinguish one element from another.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur—this distinction is captured by the terms “may” and “may be.”

The best mode for carrying out the innovation has been described for purposes of illustrating the best mode known to the applicant at the time and enable one of ordinary skill in the art to practice the innovation, including making and using devices or systems and performing incorporated methods. The examples are illustrative only and not meant to limit the innovation, as measured by the scope and merit of the claims. The innovation has been described with reference to preferred and alternate embodiments. Obviously, modifications and alterations will occur to others upon the reading and understanding of the specification. It is intended to include all such modifications and alterations insofar as they come within the scope of the appended claims or the equivalents thereof The patentable scope of the innovation is defined by the claims, and may include other examples that occur to one of ordinary skill in the art. Such other examples are intended to be within the scope of the claims if they have structural elements that do not differentiate from the literal language of the claims, or if they include equivalent structural elements with insubstantial differences from the literal language of the claims.

It will be appreciated that various of the above-disclosed and other features and functions, or alternatives thereof, may be desirably combined into many other different systems or applications. It will be further appreciated that various presently unforeseen or unanticipated alternatives, modifications, variations or improvements therein may be subsequently made by those skilled in the art which are also intended to be encompassed by the following claims.

1. A semiconductor package, comprising:
a cap comprising:
a first window wafer comprising a first face and opposing second face, wherein the first face and second face are mutually parallel, and wherein the first face and/or second face includes an antireflective surface;
a second window wafer comprising a first face and opposing second face; and
a spacer wafer that is perforated with a plurality of through-holes extending from a first face of the spacer wafer to an opposing second face of the spacer wafer, wherein the spacer wafer is disposed between the first window wafer and the second window wafer with the first window wafer bonded to the first face of the spacer wafer and the second window wafer bonded to the second face of the spacer wafer,
wherein the first window wafer, second window wafer, and spacer wafer together define a cavity in the cap; and
an edge-emitting laser diode disposed on a submount and configured to direct a laser beam at normal incidence to the first face of the first window wafer,
wherein the cap is mounted on the submount with the edge-emitting laser diode enclosed in the cavity.

2. The semiconductor package of claim 1, wherein the antireflective surface comprises an antireflective coating, a filter coating, or a textured surface configured to form an antireflective topography.

3. The semiconductor package of claim 2, wherein the textured surface comprises a motheye topography in which textured areas are formed in a matrix of discrete rectangular areas.

4. The semiconductor package of claim 1, wherein the first face of the first window wafer is disposed proximal to the edge-emitting laser diode and includes the antireflective surface.

5. The semiconductor package of claim 4, wherein the second face of the first window wafer is disposed distal to the edge-emitting laser diode and is bonded to an array of lenses or microlenses.

6. The semiconductor package of claim 1, wherein the first window wafer and/or the second window wafer is a dual side polished wafer.

7. The semiconductor package of claim 1, wherein the first window wafer comprises DSP fused silica, glass, sapphire, Borofloat 33 glass, or silicon.

8. The semiconductor package of claim 1, wherein the first and second window wafers each have a thickness of 0.2 mm to 0.8 mm and the spacer wafer has a thickness of 0.5 mm to 3.5 mm.

9. The semiconductor package of claim 1, wherein the spacer wafer is configured to have a substantially similar coefficient of thermal expansion (CTE) as the first and second window wafers.

10. The semiconductor package of claim 9, wherein the spacer wafer is comprised of substantially the same material as the first window wafer and/or the second window wafer.

11. The semiconductor package of claim 1, wherein the first window wafer, second window wafer, and spacer wafer each have a circular shape with a diameter between 150 mm and 200 mm.

12. The semiconductor package of claim 1, wherein the spacer wafer comprises Invar, silicon, Kovar, fused silica, glass, or sapphire.

13. The semiconductor package of claim 1, wherein the submount is made of ceramic.

14. The semiconductor package of claim 1, wherein the plurality of through-holes are rectangular, triangular, or circular.

15. A method for manufacturing a cap for use in an EELD semiconductor package, the method comprising:
bonding first and second window wafers to opposing faces of a spacer wafer to form a bonded wafer sandwich, wherein the spacer wafer is disposed between the first window wafer and the second window wafer in the bonded wafer sandwich, wherein the spacer wafer is perforated with a plurality of through-holes extending therethrough between the opposing faces of the spacer wafer, wherein a face of the first window wafer and/or the second window wafer includes an antireflective surface;
stacking multiple bonded wafer sandwiches on top of one another to form a block, wherein adjacent bonded wafer sandwiches are secured together using an adhesive;
cutting through the block to form at least one plate;
processing the plate by metallizing lip portions of the plate;
cutting through the plate to form bars; and
removing the adhesive from the bars to produce caps.

16. The method of claim 15, wherein the first and second window wafers are bonded to the spacer wafer via solder bonding, direct bonding, anodic bonding, laser bonding, or adhesive bonding.

17. The method of claim 16, wherein the bonding of the first and second window wafers to the spacer wafer is carried out in two successive steps, comprising:
bonding the spacer wafer to the first window wafer; and
bonding the second window wafer to the spacer wafer.

18. The method of claim 15, wherein the adhesive is a temporary adhesive.

19. The method of claim 15, wherein cutting through the block to form at least one plate comprises:
cutting through the through-holes within each bonded wafer sandwich to form cavities in the at least one plate.

20. The method of claim 15, wherein the adhesive is removed by exposing the bars to solvent.

21. The method of claim 15, wherein processing the plate further comprises:
cleaning a surface of the plate; and
grinding the surface flat prior to metallizing lip portions of the plate.

22. A method for making a cap for use in an EELD semiconductor package, the method comprising:
processing wafers to form a bonded wafer comprising:
bonding first and second window wafers to opposing faces of a spacer wafer to form a bonded wafer sandwich, wherein the spacer wafer is disposed between the first window wafer and the second window wafer in the bonded wafer sandwich, wherein the spacer wafer is perforated with a plurality of through-holes extending therethrough between the opposing faces of the spacer wafer, and wherein a face of the first window wafer and/or the second window wafer includes an antireflective surface;
cutting through the bonded wafer sandwich to form caps that each include a cavity; and
processing the cap by metallizing a lip of the cap.

23. The method of claim 22, wherein the first and second window wafers are bonded to the spacer wafer via solder bonding, direct bonding, anodic bonding, laser bonding, or adhesive bonding.

24. The method of claim 22, wherein cutting through the bonded wafer sandwich comprises:
cutting through the through-holes within the bonded wafer sandwich; and
cutting through spacer wafer walls defining the through-holes to produce the caps.

25. The method of claim 22, wherein processing the cap further comprises:
cleaning a surface of the cap; and
grinding the surface flat prior to metallizing the lip of the cap.

26. A method for making a cap for use in an EELD semiconductor package, the method comprising:
processing wafers to form a bonded wafer comprising:
bonding first and second window wafers to opposing faces of a spacer wafer to form a bonded wafer sandwich, wherein the spacer wafer is disposed between the first window wafer and the second window wafer in the bonded wafer sandwich, wherein the spacer wafer is perforated with a plurality of through-holes extending therethrough between the opposing faces of the spacer wafer, and wherein a face of the first window wafer and/or the second window wafer includes an antireflective surface;
cutting through the bonded wafer sandwich to form strips that each include a plurality of cavities;
mounting the strips on a carrier or in an array holder;
processing the strips by metallizing a lip of each strip; and
cutting through the mounted strips to produce caps that each include a cavity.

27. The method of claim 26, wherein the first and second window wafers are bonded to the spacer wafer via solder bonding, direct bonding, anodic bonding, laser bonding, or adhesive bonding.

28. The method of claim 26, wherein cutting through the bonded wafer sandwich comprises:
cutting through the through-holes within the bonded wafer sandwich; and
selectively cutting through spacer wafer walls defining the through-holes to produce the strips.

29. The method of claim 26, wherein the strips each include four cavities.

30. The method of claim 26, wherein processing the strips further comprises:
cleaning a surface of the strips; and
grinding the surface flat prior to metallizing the lips of the strips.
